(19) United States
(12) Patent Application Publication
(10) Pub. No.: US 2016/0299202 A1
(43) Pub. Date: Oct. 13, 2016

(54) MAGNETIC RESONANCE IMAGING APPARATUS AND CONTROL METHOD THEREOF

(71) Applicant: HITACHI, LTD., Tokyo (JP)

(72) Inventors: Kenta SAKURAGI, Tokyo (JP); Masahura ONO, Tokyo (JP); Kentaro SUNAGA, Tokyo (JP)

(21) Appl. No.: 15/038,567

(22) PCT Filed: Dec. 4, 2014
(86) PCT No.: PCT/JP2014/082057

§ 371 Date: May 23, 2016

(30) Foreign Application Priority Data
Dec. 18, 2013 (JP) 2013-260707

(51) Int. Cl. G01R 33/28; G01R 33/567

(52) U.S. Cl. CPC G01R 33/288; G01R 33/5673

(57) ABSTRACT

Imaging is avoided being interrupted due to an actually measured SAR value, obtained by a fluctuation in an object's biological information, exceeding a limit value. For this, the CPU 71 computes the predicted SAR value in response to a period of the biological information to determine that the predicted SAR value does not exceed the limit value. The generation of the gradient magnetic field and the generation of the high frequency magnetic field are controlled on the basis of the determination, thereby performing an imaging operation. An MRI image is configured on the basis of the detected nuclear magnetic resonance signal.

### TECHNICAL FIELD

The present invention relates to a magnetic resonance imaging (hereinafter, referred to as MRI) apparatus.

### BACKGROUND ART

MRI apparatuses are apparatuses that measure a nuclear magnetic resonance (hereinafter, referred to as NMR) signal which is generated by atomic nucleus spin of atoms constituting tissues of an object, particularly, a human body, for example, hydrogen atoms, and that two-dimensionally or three-dimensionally image the form or function of, for example, the head, abdomen, or limbs of the object.

In imaging, the NMR signal is provided with phase encoding varying depending on a gradient magnetic field and is frequency-encoded, whereby the signal is measured as time-series data. The measured NMR signal is reconfigured as an image by two-dimensional or three-dimensional Fourier transform.

Safety problems to be considered when the MRI apparatus is clinically used include a problem related to an electromagnetic wave. According to the third edition of IEC60601-2-33, the amount of absorption of a high frequency magnetic field pulse (hereinafter, referred to as an RF pulse) per unit time and unit mass is set as a specific absorption rate (referred to as an SAR) to give definitions as in (Expression 1) to (Expression 3), and restriction is applied so that a human body is irradiated with no more electromagnetic waves by the upper limit thereof.

$$\begin{matrix}whole body S A R ( W \text{/} kg ) = \frac{W ( W )}{M ( kg )} & ( 1 ) \\ partial body S A R ( W \text{/} kg ) = \frac{{W}_{p} ( W )}{{M}_{p} ( kg )} & ( 2 )\end{matrix}$$

local SAR (W/kg)=energy per unit time which is absorbed into any 10 g (3)

Here, a whole body SAR is obtained by dividing energy W of electromagnetic waves absorbed into the whole body of an object by amass M of the object, a partial body SAR is obtained by dividing energy Wₚ of electromagnetic waves absorbed into a desired area of the object by a mass Mₚ of the desired area of the object, and a local SAR is energy per unit time which is absorbed into any 10 g.

PTL 1 discloses the change of a parameter which is performed so as not to exceed an SAR limit, particularly, with respect to multiple times of scanning. PTL 2 discloses SAR prediction of scanning and prediction of multiple times of scanning.

### CITATION LIST

### Patent Literature

PTL 1: JP-A-2006-95278

PTL 2: International Publication WO 2011/122430

### SUMMARY OF INVENTION

### Technical Problem

It is necessary to control imaging within an SAR limit value for the safety of an object in accordance with the provision related to a limit of an SAR. An imaging method of a general MRI apparatus includes a method of monitoring biological information such as a pulse wave and an electrocardiogram and performing imaging in a simultaneous phase in order to reduce an artifact resulting from the movement of an organ or the burden of an object's breath-holding. In a case where an imaging timing becomes earlier and the SAR limit is exceeded due to a change in the biological information, it is necessary to stop imaging, which results in a deterioration of workability such as the necessity of performing imaging again.

PTL 1 and PTL 2 disclose the prediction of an SAR, but do not mention about the prediction of an SAR or the control of imaging when biological information changes. That is, in the above-mentioned PTLs, a change in biological information is not considered, and the necessity of consideration is not mentioned. Regarding an object 11, not only a relatively healthy person but also any one of people having various diseases may become an object. Naturally, the necessity of examining a person in a serious disease condition is higher than that of a healthy person, and thus it is preferable to consider a case where an object has a serious disease. In many cases, biological information may be suddenly disturbed in an object having a serious disease.

On the other hand, it is preferable to shorten the time required for imaging such a person having a serious disease as much as possible as compared to a relatively healthy person, to thereby reduce burden. A deterioration of workability such as the necessity of performing imaging again leads to not only the degradation of work efficiency but also an increase in an object's burden. This is a serious problem for a patient having a serious symptom.

An object of the invention is to provide an MRI apparatus capable of suppressing the interruption of imaging due to an actually measured SAR value exceeding a limit value.

### Solution to Problem

According to the invention, there is provided a magnetic resonance imaging apparatus including a static magnetic field generation unit that generates a static magnetic field in a space in which an object is accommodated, a gradient magnetic field generation unit that generates a gradient magnetic field so as to be superimposed on the static magnetic field, a high frequency magnetic field generation unit that generates a high frequency magnetic field to be emitted to the object, a sequencer that controls the generation of the gradient magnetic field and the generation of the high frequency magnetic field in accordance with a pulse sequence, a signal detection unit that detects a nuclear magnetic resonance signal, a control unit that computes a predicted SAR value, and a biological information reception unit (90) that receives biological information. The sequencer controls the generation of the gradient magnetic field and the generation of the high frequency magnetic field in synchronization with the biological information. The control unit computes a predicted SAR value to determine whether or not the predicted SAR value exceeds a limit value, on the basis of a length of a period of the biological information. The generation of the gradient magnetic field and the generation of the high frequency magnetic field are controlled to perform an imaging operation on the basis of the control unit determining that the predicted SAR value does not exceed the limit value, and an MRI image is generated on the basis of the nuclear magnetic resonance signal detected by the signal detection unit.

### Advantageous Effects of Invention

According to the invention, it is possible to obtain an MRI apparatus capable of suppressing the interruption of imaging due to an actually measured SAR value exceeding a limit value.

### BRIEF DESCRIPTION OF DRAWINGS

FIG. 1 is a block diagram showing a configuration of an MRI apparatus according to an embodiment of the invention.

FIG. 2 is a flow chart showing an outline of an operation of an MRI apparatus according to the embodiment of the invention.

FIG. 3 is a time table showing SAR prediction computation and an operation of measuring an actually measured SAR in the flow chart described in FIG. 2.

FIG. 4 is a flow chart showing an operation of a control unit in the time table described in FIG. 3.

FIG. 5 is a time table showing a method of synchronously imaging an MRI image by dividing a pulse sequence, according to still another example of the invention.

FIG. 6 is a flow chart showing an operation of a control unit in the time table described in FIG. 5.

FIG. 7 is a time table showing a method of performing SAR prediction from one period prior to biological information, according to still another example of the invention.

FIG. 8 is a flow chart showing an operation of a control unit in the time table described in FIG. 7.

FIG. 9 is a time table showing a method of performing SAR prediction from a past amount of variation of biological information, according to still another example of the invention.

FIG. 10 is a time table showing a countermeasure in a case where a predicted SAR value exceeds a limit value, according to still another example of the invention.

FIG. 11 is a flow chart showing an operation of a control unit in the time table described in FIG. 10.

FIG. 12 is a diagram showing display contents displayed on a display in the flow chart described in FIG. 11.

FIG. 13 is a time table showing a method of automatically skipping application based on a pulse sequence in a case where a predicted SAR value exceeds a limit value, according to still another example of the invention.

FIG. 14 is a flow chart showing an operation of a control unit in the time table described in FIG. 13.

FIG. 15 is a diagram showing display contents displayed on a display in the flow chart described in FIG. 14.

FIG. 16 is a time table showing a method of changing a parameter of a pulse sequence in a case where a predicted SAR value exceeds a limit value, according to still another example of the invention.

FIG. 17 is a flow chart showing an operation of a control unit in the time table described in FIG. 16.

FIG. 18 is a diagram showing display contents displayed on a display in the flow chart described in FIG. 17.

FIG. 19 is a flow chart showing still another example of the invention.

### DESCRIPTION OF EMBODIMENTS

In all drawings used to describe an embodiment of the invention, components or orders having substantially the same function or performing substantially the same action are denoted by the same reference numerals and signs, and a repeated description thereof may be omitted. In addition, in this specification, “imaging” and “photographing” are used as substantially the same meaning and are not specially used properly. In this specification, terms of “computation” and “calculation” not only mean simply executing an algebraic computation but also are used as including a method of storing data obtained in advance by computation, measurement, simulation or the like as a multi-dimensional data table such as a two-dimensional or three-dimensional data table, retrieving the data table, and performing a process of interpolating a retrieval result to thereby obtain a preferable value and condition by various methods such as a process of obtaining a value satisfying a condition. Hereinafter, an embodiment (hereinafter, referred to as an example) of an MRI apparatus to which the invention is applied, with reference to the accompanying drawings.

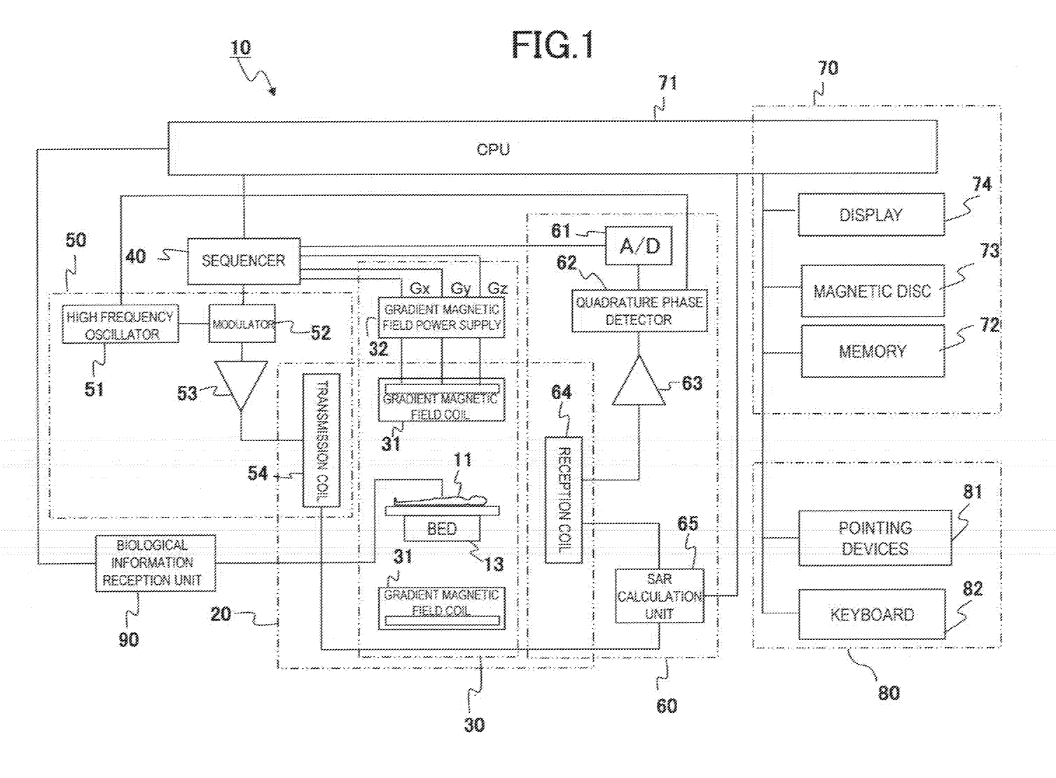

First, the overall outline of an example of an MRI apparatus to which the invention is applied will be described with reference to FIG. 1. FIG. 1 is a block diagram showing the overall configuration of an example of an MRI apparatus to which the invention is applied. The MRI apparatus obtains a tomographic image of an object using an NMR phenomenon. As shown in FIG. 1, an MRI apparatus 10 includes a static magnetic field generation unit that generates a static magnetic field in a static magnetic field space 20 indicated by a dotted line frame, a gradient magnetic field generation unit 30 that generates a gradient magnetic field, a sequencer 40, a high frequency magnetic field generation unit 50, a signal detection unit 60, a processing unit 70, an operation unit 80, and a biological information reception unit 90. Meanwhile, the static magnetic field generation unit is not shown in the drawing.

In the static magnetic field space 20, an object 11 is placed therein, and an uniform static magnetic field is generated in a direction perpendicular to the body axis of the object 11 in a case of a vertical magnetic field system and in a direction of the body axis of the object 11 in a case of a horizontal magnetic field system. In order to generate a static magnetic field, a static magnetic field generation source of a permanent magnet type, a normal conductive type, or a superconductive type is disposed in the vicinity of the object 11.

The gradient magnetic field generation unit 30 includes gradient magnetic field coils 31 that generate a gradient magnetic field in directions of three axes of X, Y, and Z, which are coordinate systems (stationary coordinate systems) of the MRI apparatus 10, so as to be superimposed on a static magnetic field of the static magnetic field space 20, and gradient magnetic field power supplies 32 that drive the respective gradient magnetic field coils. The gradient magnetic field power supplies 32 of the respective coils are driven in accordance with a command from the sequencer 40 to be described later, and thus gradient magnetic fields Gₓ, G_{y}, and G_{z} are generated in the directions of the three axes of X, Y, and Z. During imaging, a slice direction gradient magnetic field pulse (Gₛ) is applied in a direction perpendicular to a slice surface (imaged cross-section) to set a slice surface with respect to the object 11, and a phase encoding direction gradient magnetic field pulse (Gₚ) and a frequency encoding direction gradient magnetic field pulse (Gf) are applied so as to be perpendicular to the slice surface and in the remaining two directions perpendicular to each other to encode pieces of positional information in the respective directions to an echo signal.

The sequencer 40 repeatedly applies a control signal in accordance with any predetermined pulse sequence of a high frequency magnetic field pulse (hereinafter, referred to as an RF pulse) and a gradient magnetic field pulse. The sequencer 40 operates under the control of a central processing unit (hereinafter, referred to as a CPU) 71 and transmits various commands necessary for data collection of a tomographic image of the object 11 to the gradient magnetic field generation unit 30, the high frequency magnetic field generation unit 50, and the signal detection unit 60.

Here, the CPU 71 operates as a control unit that controls the operation of the MRI apparatus 10. The control unit may be constituted by one CPU 71, or may be constituted by a plurality of processing devices (CPU) that separately share necessary functions. The control unit performs a computation process and the like in addition to performing control. In addition, biological information 92 is received from the biological information reception unit 90 to be described below, thereby controlling the sequencer 40 so that a pulse sequence is performed in synchronization with the biological information 92.

The high frequency magnetic field generation unit 50 irradiates the object 11 with an RF pulse in order to make nuclear magnetic resonance occur in the atomic nucleus spin of atoms constituting a biological tissue of the object 11. The high frequency magnetic field generation unit 50 includes a high frequency oscillator 51, a modulator 52, a high frequency amplifier 53, and a transmission coil 54 which is a high frequency coil on a transmission side. The RF pulse which is output from the high frequency oscillator 51 is amplitude-modulated by the modulator 52 at a timing according to an instruction received from the sequencer 40, and the amplitude-modulated RF pulse is amplified by the high frequency amplifier 53 and is then supplied to the transmission coil 54 disposed in proximity to the object 11, and thus the object 11 is irradiated with electromagnetic waves.

The signal detection unit 60 detects an echo signal (hereinafter, referred to as an NMR signal) which is emitted by nuclear magnetic resonance of atomic nucleus spin of atoms constituting a biological tissue of the object 11. The signal detection unit 60 includes a reception coil 64 which is a high frequency coil on a reception side, a signal amplifier 63, a quadrature phase detector 62, an A/D converter 61, and an SAR calculation unit 65. An NMR signal, which is a response to the object 11, induced by electromagnetic waves emitted from the transmission coil 54 is detected by the reception coil 64 disposed in proximity to the object 11, is amplified by the signal amplifier 63, and is divided into signals of two systems perpendicular to each other by the quadrature phase detector 62 at a timing according to an instruction received from the sequencer 40. Each of the signals obtained by the division is converted into a digital amount by the A/D converter 61 and is transmitted to the processing unit 70.

In addition, the amount of electromagnetic waves, emitted from the transmission coil 54, which absorb into the object 11 is calculated by the SAR calculation unit 65. An SAR calculated by the SAR calculation unit 65 is transmitted to the CPU 71 and is compared with an SAR limit, and a comparison result is registered in, for example, a memory 72.

The processing unit 70 performs various data processing, the display and storage of a processing result, and the like. The processing unit 70 includes a processor such as the CPU 71, a storage device such as the memory 72, an external storage device such as an optical disc or a magnetic disc 73 which has a storage function, and a display 74 such as a liquid crystal display (LCD) which has a display function. When the signal detection unit 60 receives a signal or data, the CPU 71 performs a process such as signal processing or image reconstruction using the memory 72 as a work area, displays a tomographic image of the object 11 which is a result thereof on the display 74, and records the tomographic image in the magnetic disc 73 which is an external storage device.

The operation unit 80 inputs various control information regarding the MRI apparatus 10 and control information of a process performed by the processing unit 70. The operation unit 80 includes, for example, a pointing device 81 such as a trackball, a mouse, or a pad, and a keyboard 82. The operation unit 80 is disposed in proximity to the display 74, and an operator can interactively instruct the MRI apparatus 10 to perform various processes through the operation unit 80 while viewing the display 74. In addition, the pointing device 81 may include, for example, a touch panel as one of input devices, and the touch panel may be provided on a display surface of the display 74. In this manner, an input unit such as a touch panel is provided on the display surface of the display 74, and thus it is possible to perform an input operation in response to a display image of the display 74.

The biological information reception unit 90 receives biological information regarding the object 11, converts a received signal into a digital amount, and transmits the converted signal to the CPU 71. The CPU 71 calculates, for example, a phase of a pulse which is biological information, gives an instruction to the sequencer 40 so that a pulse is repeatedly applied for each phase, transmits a control instruction corresponding to the phase of the biological information to the gradient magnetic field power supply 32, the modulator 52, and the A/D converter 61 from the sequencer 40, and applies an RF pulse to the object 11 in response to the phase of the biological information. In addition, an NMR signal generated on the basis of the application of the RF pulse is detected in response to the phase of the biological information. In this manner, it is possible to obtain a high-quality image with a reduced artifact resulting from the movement of organs.

Meanwhile, in FIG. 1, the transmission coil 54 and the gradient magnetic field coil 31 are disposed within a static magnetic field space accommodating the object 11 so as to face the object 11 in a case of a vertical magnetic field system and to surround the object 11 in a case of a horizontal magnetic field system. In addition, the reception coil 64 is disposed so as to face or surround the object 11.

At present, a nuclide to be imaged of the MRI apparatus 10, which is spreading for a clinical use, is a hydrogen atomic nucleus (proton) which is a main constituent material of the object 11. Information regarding the spatial distribution of proton density or the spatial distribution of a relaxation time of an excitation state is imaged, thereby two-dimensionally or three-dimensionally imaging an area such as a form or function of the head, abdomen, or limbs of a human body.

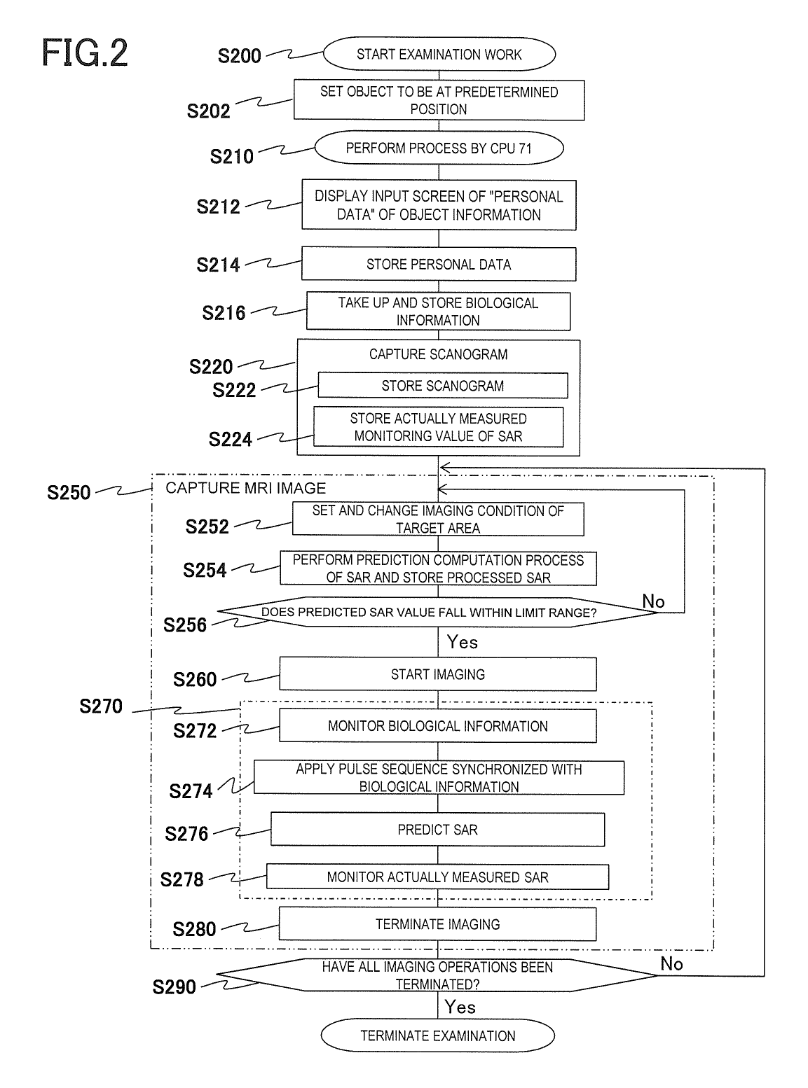

Next, a description will be given of the prediction computation of an SAR value which is performed when an MRI apparatus having the above-mentioned configuration is used. FIG. 2 is a flow chart showing a processing operation for imaging of the CPU 71, and the CPU 71 repeatedly detects biological information 92 through the biological information reception unit 90 during a series of imaging operations and calculates a predicted SAR value 270 in an imaging condition which is set using the detected biological information 92. The CPU 71 confirms that the calculated predicted SAR value 270 falls within a limit range, and thus an imaging operation is started. The CPU 71 performs control for performing imaging on the object 11 by the start of the imaging operation.

The biological information 92 of the object 11 has an attribute of greatly changing for a short period of time, unlike information regarding a scanogram of the object 11 or information such as a body weight. The CPU 71 repeatedly detects the biological information 92 to repeatedly compute the predicted SAR value 270 on the basis of the detected biological information 92, and observes whether or not the computed predicted SAR value 270 is a limit value. Further, an actually measured SAR value 67 is measured through the SAR calculation unit 65, and it is observed whether or not the actually measured SAR value 67 exceeds a limit value.

An MRI image of the object 11 using the MRI apparatus 10 is captured by an imaging operation started in step S200. When the imaging operation is started, the object 11 is set in the MRI apparatus 10 (step S202). Specifically, the object 11 is placed on a top board of a bed 13 shown in FIG. 1 so as to be fixed. Further, other necessary operations are performed.

The CPU 71 captures an MRI image in accordance with a process of predicting an SAR or an imaging condition which is set, on the basis of a control program which is stored in a storage device such as a server in advance, and starts a process for storing the captured image in a storage device such as the magnetic disc 73 (step S210).

In a series of processing flows of the CPU 71 starting from step S210, a process of inputting personal data of an object (step S214), a process of inputting biological information (step S216), a process of capturing a scanogram (step S220), a process of capturing an MRI image (step S250), and the like are described as a flow of a series of continuous processes for convenience of description. However, in an actual processing operation of the CPU 71, the CPU 71 does not execute a series of continuous programs, a flow starting from step S210 described in FIG. 2 is divided into a plurality of application programs for each function, and the application programs are separately executed in an execution condition suitable for a processing function.

Each of the application programs is started up and executed in a determined execution condition by, for example, an operating system which is a management program. For example, any application program may be repeatedly executed at a fixed short period, another application program may be executed in association with the execution of a specific application program having a special relationship therewith, or still another application program may be executed by linking an operator's operation as an event to a specific event. A detailed description of an execution condition, a start-up state, a termination process associated with the termination of execution, and the like of each of the application programs results in an extremely complicate explanation, and thus comprehensive processing results of the application programs operating as described above will be described as a line of flow charts indicating processing contents of the CPU 71 which is started in step S210 described in FIG. 2.

The CPU 71 displays an input screen or the like for inputting personal data which is object information or the biological information 92 on the display 74 (step S212), and the personal data which is object information or the biological information 92 is input to the MRI apparatus 10 in accordance with display contents displayed by the CPU 71 (step S214, step S216). The object information includes personal data, such as age, height, and weight, and biological information such as a heart rate, a pulse wave, and an electrocardiographic waveform. In an example described in this example, the personal data and the biological information 92 are input by different steps.

As in this example, an advantage of the separately inputting of personal data and biological information is in that the input methods thereof are different from each other. The personal data is information which has a property of not changing for a short period of time and of which the value does not change during imaging. On the other hand, the biological information 92 is information which tends to change for a short period of time and which is preferably taken up when the information is used for computation, for example, immediately before the information is used, and has different importances of taking-up timing.

It is preferable that the biological information 92 is taken up immediately before the use thereof as much as possible. In this example, a detection unit detecting biological information is provided like the biological information reception unit 90 shown in FIG. 1, so that the biological information is taken up from the biological information reception unit 90 at a close timing when the biological information 92 is used. As described above, the biological information 92 has a property of changing for a short period of time, and is preferably taken up near the use thereof as much as possible. In particular, in the MRI apparatus 10, the object 11 damages his or her health in many cases, and there is a higher possibility of the biological information 92 suddenly changing than in a case of a healthy person. For this reason, it is preferable that the biological information 92 is measured immediately before the necessity thereof as much as possible.

In this example, the CPU 71 takes up and stores the biological information 92 such as a heart rate, a pulse wave, and an electrocardiographic waveform through the biological information reception unit 90 in step S216, as an example. In an actual apparatus, biological information is not required to be taken up at the position of step S216 shown in FIG. 2, and biological information 92 may be taken up at a timing when the biological information 92 is used. For example, in a configuration in which a program having a function of taking up the biological information 92 is provided and is repeatedly executed at an extremely short period so as to hold the taken-up biological information in a specific temporary storage address, the latest information of the biological information 92 is held in the temporary storage address at all times. In a case where a process of using biological information is performed, the biological information 92 stored in the temporary storage address is used, thereby allowing the process to be performed using the latest biological information 92.

In capturing a diagnostic image by the MRI apparatus 10, a scanogram which is an image for determining an imaging position is captured and stored in step S220. In the capturing of a scanogram by step S220, a scanogram is captured by step S222 and is stored in a storage device such as the magnetic disc 73. In addition, in the capturing of a scanogram, the output of an RF pulse is smaller than in the capturing of an MRI image which is to be performed below, but an RF pulse is actually emitted from the transmission coil 54, and thus it is possible to obtain, as a monitor, the value of an SAR based on the actual emission of the RF pulse from the SAR calculation unit 65. The obtained value of the SAR is based on the RF pulse which is actually emitted, and can be measured as an actually measured value in a case where the object 11 is actually irradiated with the RF pulse. The SAR is based on the mass of a measurement area of an individual, and the like, and an absorption state of the RF pulse is different depending on an individual. The monitoring of an actually measured value of an SAR in advance with respect to the capturing of an MRI image is extremely useful for an improvement in the prediction accuracy of the SAR.

Step S250 shows an outline of the operation of the MRI apparatus 10 which is related to the capturing of an MRI image of the object 11, and particularly shows an outline of a process related to an SAR using the biological information 92.

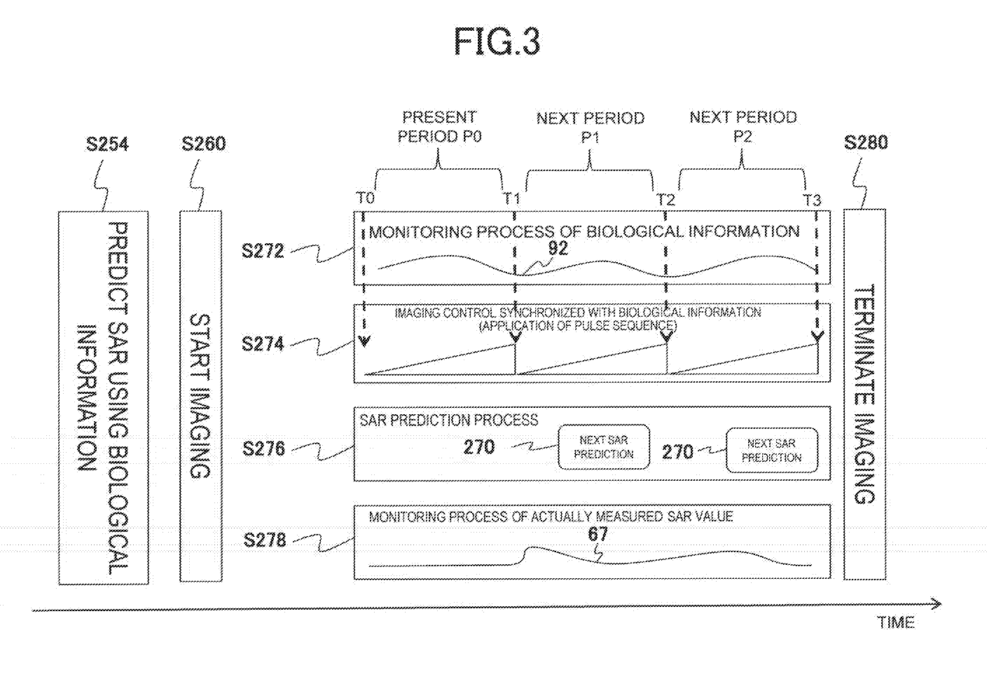

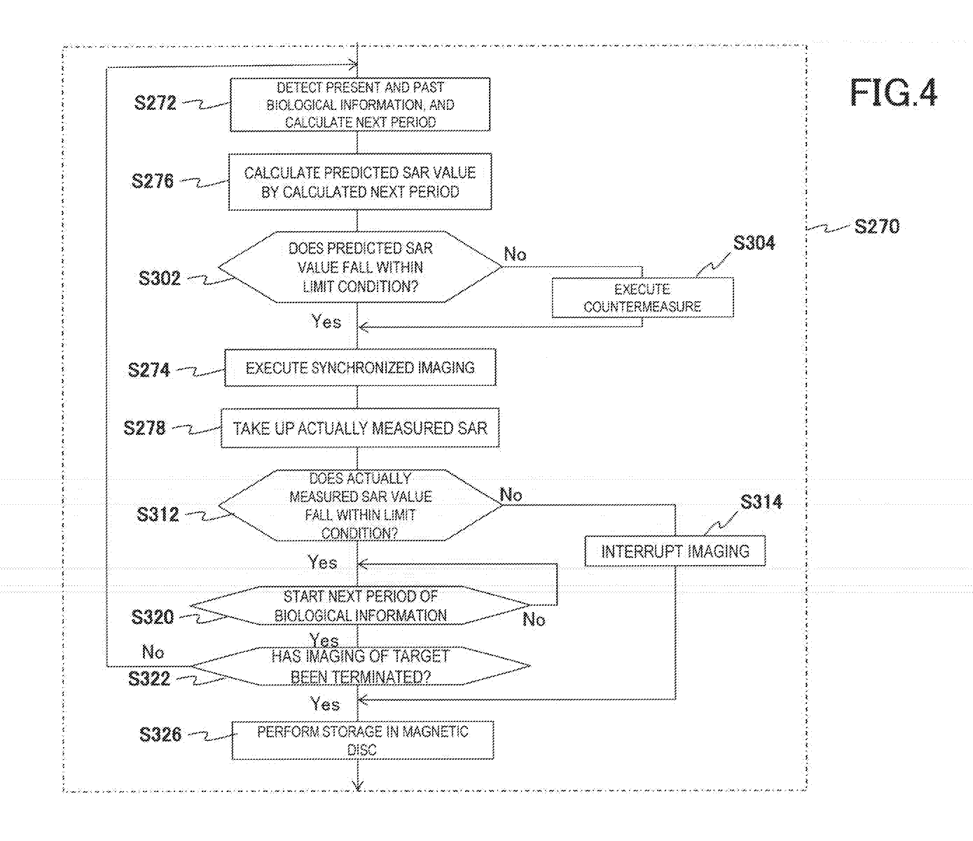

In addition, the time table thereof is shown in FIG. 3. Further, an example of a specific procedure of a process of step S270 in step S250 is shown in FIG. 4.

In step S252, the input of an imaging condition related to an area to be imaged or the change of an imaging condition which is set in advance is performed in accordance with an input screen from the CPU 71 or a display that suggests the input of an imaging condition. The imaging condition is determined on the basis of the body type of the object 11 or examination contents. In step S254, the prediction computation of an SAR is performed by the CPU 71 on the basis of the imaging condition which is input or changed, and a computation result is stored. Further, it is determined in step S256 whether or not a predicted value of the computed SAR satisfies a limit condition, that is, whether the predicted value of the computed SAR falls within a limit range. In a case where the predicted value does not satisfy the limit condition, that is, falls outside the limit range, the flow returns to step S252, and the reset of an imaging condition, that is, the change of an imaging condition is performed.

The prediction computation process of an SAR, which is performed using personal data which is object information or biological information by the CPU 71 in step S254, is performed on the basis of (Expression 4) to (Expression 6). Here, W denotes an SAR absorptivity and is, for example, a statistical average value of an SAR absorptivity when each area of the object 11 is irradiated with an RF pulse. In addition, PowerSeq (W) represents an irradiation power of an RF pulse in a pulse sequence and is a value obtained by calculating energy (W) of an RF pulse, which is emitted by the transmission coil 54, on the basis of an imaging parameter by the processing unit 70.

$$\begin{matrix} whole body S A R ( W \text{/} kg ) = W \frac{PowerSeq ( W )}{Mass of object M ( kg )} & ( 4 ) \\ partial body S A R ( W \text{/} kg ) = \frac{whole body S A R ( W \text{/} kg ) \times mass of object M ( kg )}{partial mass of body within irradiation range {m}_{p} ( kg )} & ( 5 ) \\ head S A R ( W \text{/} kg ) = \frac{whole body S A R ( W \text{/} kg ) \times mass of object M ( kg )}{mass of head {m}_{h} ( kg )} \times {R}_{h} & ( 6 )\end{matrix}$$

A whole body SAR defined by (Expression 4) is a numerical value obtained by dividing energy (W) of an electromagnetic wave, which is absorbed into the whole body of the object 11 by the energy of an electromagnetic wave of an RF pulse, by an object mass (weight of the object 11) M (kg). A partial body SAR defined by (Expression 5) is a numerical value obtained by multiplying a whole body SAR (W/kg) by an object mass M (kg) and dividing the resultant value by a partial mass mₚ (kg) of the body of the object 11 which is present in an irradiation range. A head SAR defined by (Expression 6) is a numerical value obtained by dividing a value, obtained by multiplying a whole body SAR (W/kg) by an object mass M (kg), by a head mass mₕ (kg) of the object 11 and multiplying the resultant value by a SAR absorptivity Rₕ of a head.

It is determined in step S256 whether of being an imaging condition in which an SAR prediction computation value satisfies an SAR limit value. Next, when an operation of starting imaging is performed by step S260, the execution of the CPU 71 proceeds from step S260 to step S270, and step S270 is performed. In step S270, the biological information 92 from the object 11 is transmitted to the CPU 71 through the biological information reception unit 90, and the CPU 71 transmits a control signal for controlling the operation of the sequencer 40 in synchronization with the transmitted biological information to the sequencer 40.

Specifically, the sequencer 40 is controlled by the control signal transmitted from the CPU 71 so that the operation of the sequencer 40 is started in synchronization with the biological information 92. For example, in a case where the sequencer 40 is constituted by a coefficient circuit, a configuration is adopted such that a control signal for executing a pulse sequence in accordance with a coefficient value of the coefficient circuit is transmitted to a control destination which is determined in advance. A coefficient operation of the coefficient circuit is started on the basis of a control signal which is supplied to the sequencer 40 from the CPU 71 in synchronization with, for example, the biological information 92, and thus it is possible to generate a control signal for executing a pulse sequence in synchronization with the biological information 92. In this manner, the sequencer 40 performs an operation of applying the control signal synchronized with the biological information 92 to the gradient magnetic field power supply 32, the modulator 52, or the A/D converter 61 (step S270).

Since the control signal transmitted from the sequencer 40 is generated in synchronization with biological information, the switching of a gradient magnetic field based on the gradient magnetic field power supply 32, the generation of an RF pulse from the transmission coil 54, and the taking-up of an NMR signal, which is received by the reception coil 64, by the A/D converter 61 are performed in synchronization with the biological information 92. In this manner, the operation of the sequencer 40 is synchronized with biological information, and thus it is possible to perform an operation based on the pulse sequence in synchronization with biological information and to perform MRI imaging in synchronization with biological information.

In addition, in step S270, the monitoring of the biological information 92 for taking up the latest biological information 92 (step S272), the application of a control signal based on a pulse sequence synchronized with the biological information 92 (step S274), the prediction computation of an SAR based on biological information (step S276), and the monitoring of an actually measured SAR (step S278) are performed. It is determined whether or not the computed predicted SAR value 270 or the actually measured SAR value 67 falls within a limit of an SAR. Further, pieces of data such as the biological information 92 which is temporarily stored in the memory 72, the acquired diagnostic image, the calculated predicted SAR value 270, and the actually measured SAR value are stored in the magnetic disc 19, and a statistical process or the like is performed on the biological information 92 which is collected (step S270).

After the capturing of the diagnostic image is terminated in step S280, it is determined whether or not the capturing of all of the diagnostic images has been terminated. For example, in a case where a diagnostic image is captured in a different condition such as a different contrast or a different cross-section, the execution of an imaging operation of the CPU 71 proceeds to step S252 again, and an imaging condition for new imaging is set in step S252. In this manner, step S252 to step S280 mentioned above are repeatedly performed. When the capturing of all of the diagnostic images with respect to the object 11 is terminated, a series of examination operations from step S290 is terminated.

FIG. 3 is a time table showing an operation state of step 270 related to the capturing of a diagnostic image in the flow chart of FIG. 2. As described in FIG. 2, computation based on each of (Expression 4) to (Expression 6) is performed on the predicted SAR value 270 in step S254 of FIG. 3 on the basis of personal data, a measurement result of a scanogram, and the biological information 92. In a case where the computed predicted SAR value 270 is smaller than an SAR limit value, imaging is started in step S260. It is assumed that the present position is in a state of a present period P₀. An imaging operation at the present period P₀ is performed, the actually measured SAR value 67 at the present period P₀ described in step S278 is monitored, and the actually measured SAR value 67 at the present period P₀ is taken up into the processing unit 70 from the SAR calculation unit 65.

In FIG. 3, a monitoring value of the biological information 92 represents an output of the biological information reception unit 90. In a state of the present period P₀, a period coming next is a next period P₁, and a period coming subsequently to the next is a next subsequent period P₂. The biological information 92 in the next period P₁ and the next subsequent period P₂ and the actually measured SAR value 67 are not actually present at the present point in time. These are information that are measured in the future.

In addition, the CPU 71 transmits a synchronization signal for synchronizing the operation of the sequencer 40 with biological information to the sequencer 40 on the basis of the biological information 92. For example, the synchronization signal is transmitted at a timing TO, and the synchronization signal is transmitted to the sequencer 40 from the CPU 71 in the next period P₁, the next subsequent period P₂, and a period to the next at timings T₁, T₂, and T₃, respectively. Hereinafter, this operation is continuously performed until the imaging is terminated. The sequencer 40 performs a sequence operation synchronized with the biological information 92 on the basis of the synchronization signal, and transmits a control signal based on the sequence operation to the gradient magnetic field power supply 32, the modulator 52, and the A/D converter 61.

The monitoring process (step S272) of the biological information 92 which is a process specifically performed in step S270 described in FIG. 2, the application process (step S274) using a pulse sequence synchronized with the biological information 92, the SAR prediction process (step S276), and the monitoring of an actually measured SAR (step S278) are described in FIG. 3 as a time table, and an example of execution contents of the CPU 71 related to step S270 is shown in FIG. 4.

In a case where the CPU 71 operates in the present period P₀, the biological information 92 in the present period P₀ is taken up in step S302 described in FIG. 4, and a period of biological information 92 in the next period P₁ is calculated on the basis of processing results of the taken-up biological information 92 in the present period Poor pieces of biological information 92 from the past to the present (step S272).

A predicted SAR value 270 in the next period P₁ is computed by step S276 in accordance with a period of the calculated biological information 92. In this example, the prediction computation of the present period P₀ is performed, for example, at a period P₋₁ prior to the present period P₀, and a predicted SAR value 270 in the present period P₀ is computed on the basis of the present period P₀ on which the prediction computation is performed. Next, the prediction computation of the next period P₁ is performed in the present period P₀, and the prediction computation of a predicted SAR value 270 in the next period P₁ is performed on the basis of the next period P₁ on which the prediction computation is performed.

Further, the prediction computation of next subsequent period P₂ is performed in the next period P₁, and the prediction computation of a predicted SAR value 270 in the next subsequent period P₂ is performed on the basis of the next subsequent period P₂ on which the prediction computation is performed. In this manner, biological information 92 is taken up in synchronization with biological information 92, and the computation of a value of the next biological information 92 based on the taken-up biological information 92 or the computation of a predicted SAR value 270 is performed. Such a process is performed in synchronization with biological information 92.

The above-mentioned (Expression 4) to (Expression 6) are used for the computation process of a predicted SAR value 270 in the present period P₀, the computation process of a predicted SAR value 270 in the next period P₁ which are described above, and the computation process of a predicted SAR value 270 in the next subsequent period P₂. The SAR (W/kg) of each of (Expression 4) to (Expression 6) is calculated on the basis of a 6-minute average SAR value or a 10-second average SAR value. Alternatively, the SAR is calculated on the basis of the 6-minute average SAR value and the 10-second average SAR value.

With such processing, even when the biological information 92 changes, it is possible to arithmetically operate the predicted SAR value 270 in response to the change and to prevent the occurrence of a situation in which an actually measured SAR exceeds a limit range with a higher level of accuracy.

In step S302 of FIG. 4, the CPU 71 determines whether or not the computed predicted SAR value 270 exceeds a limit condition of an SAR. In a case where the computed predicted SAR value 270 falls within and does not exceed the limit condition of an SAR, the process of step S274 is performed, a control signal synchronized with actual biological information 92 is transmitted to the modulator 52 from the sequencer 40, and an RF pulse is emitted from the transmission coil 54 at a timing synchronized with the biological information 92.

In addition, a control signal synchronized with biological information 92 is transmitted to the A/D converter 61 from the sequencer 40, and an NMR signal is taken up in synchronization with the biological information 92. In this manner, an imaging process is performed in synchronization with actual biological information 92.

On the other hand, in step S302, in a case where the CPU 71 determines that the predicted SAR value 270 exceeds the limit condition of an SAR, the execution of the CPU 71 proceeds to 304, and a countermeasure is taken in step S304. As the countermeasure, for example, an RF pulse which is output from the transmission coil 54 may be reduced, or imaging may be performed in a state where the lessening of the disturbance of the period of the biological information 92 is waited for and the period of the biological information 92 is extended. Various other countermeasures are considered.

As described in step S274, when imaging is performed in synchronization with the biological information 92, the actually measured SAR value 67 is monitored in step S278. Specifically, the actually measured SAR value 67 which is a computation result of the SAR calculation unit 65 is taken up by the CPU 71 as actually measured SAR value 67. In step S312, the CPU 71 monitors whether or not the actually measured SAR value 67 exceeds the limit condition of an SAR. In a case where the CPU 71 determines that the actually measured SAR value 67 exceeds the limit condition of an SAR, a process of interrupting imaging is performed in step S314.

The above description based on the flow chart of FIG. 4 is given when it is assumed that the processing operation of the CPU 71 is in the present period P₀. When a processing point in time of the CPU 71 proceeds from the present period P₀ to the next period P₁ as time passes, the execution of the CPU 71 proceeds to step S320. In step S320, the CPU 71 determines that a new period of biological information 92 has started, and the execution of the CPU 71 proceeds from step S322 to step S272 again. In this manner, the CPU 71 performs the same process even in the next period P₁. Further, the CPU 71 repeats the same process even in the next subsequent period P₂. In this manner, an imaging operation is performed in synchronization with the change in the biological information 92.

When the imaging operation is terminated in step S322 of FIG. 4, an imaging result, a detection result of the biological information 92, a result of a statistical process of the biological information 92, a result of the computed predicted SAR value 270, a measurement result of the actually measured SAR value 67, and the like are stored and saved in the magnetic disc 73 in step S326. After the process of step S326 is performed, 280 described in FIGS. 2 and 3 is performed to terminate imaging, and step S290 of FIG. 2 is performed.

### Example 1

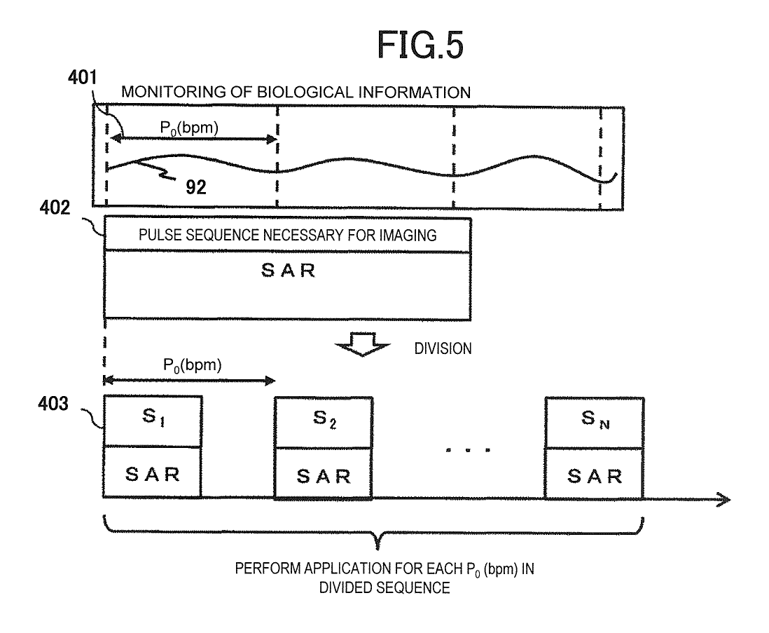

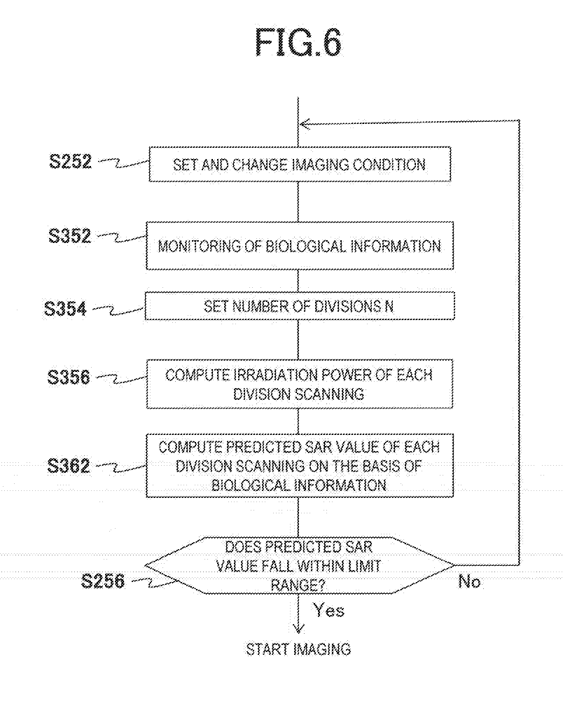

FIG. 5 is a time table illustrating one processing method related to SAR prediction computation before the execution of scanning for imaging. In addition, FIG. 6 shows a flow chart of processing of the CPU 71 which is performed to perform a process based on the time table described in FIG. 5, and is an alternative to step S252 to step S256 shown in FIG. 2. Procedures related to substantially the same process as the procedures of the flow chart described in FIG. 2 will be denoted by the same reference numerals and signs.

In step S252, an imaging condition is set, or the previous setting contents are changed. In step S352, biological information 92 is measured from the biological information reception unit 90. The biological information 92 is, for example, an electrocardiogram. For example, a period of a pulse, and the like are measured in an electrocardiogram of an object 11. The order of step S252 or step S352 is an example and may vary.

The obtained biological information 92, for example, a repetition period of an electrocardiogram is set to be P₀ (bpm). In step S354, the number of divisions N for imaging is set in order to synchronously perform imaging. When imaging is performed in synchronization with a repetition waveform of the biological information 92, a pulse sequence 402 necessary for the imaging is divided into N parts (N is a natural number), which are set to be a pulse sequence 403 divided into a plurality of parts S1 to SN. An irradiation power of an RF pulse for imaging in one period of the biological information 92 is divided into N parts as in (Expression 7).

PowerSeq(W)=PowerSeq[1](W)+PowerSeq[2](W)+ . . . +PowerSeq[N](W) (7)

When the entire scanning time based on a pulse sequence is set to be ScanTime (sec), a scanning time of the divided pulse sequence is expressed as (Expression 8).

ScanTime(sec)=ScanTime[1](sec)+ScanTime[2](sec)+ . . . +ScanTime[N](sec) (8)

An interval 401 of P₀ (bpm) is present during each pulse sequence, and thus an average SAR of a pulse sequence within a certain time is calculated as in (Expression 9) by setting the number of pulse sequences within a certain time to be k.

$$average S A R ( W \text{/} kg ) = \frac{{\sum }_{i = 1}^{k} PowerSeq [ i ]}{{\sum }_{i = 1}^{k} ( 60 / {P}_{0} )} \qquad ( 9 )$$

For example, when an SAR of a pulse sequence divided is 3 (W/kg), a scanning time is 0.5 (sec), and a period P₀ is 60 (bpm), the number of pulse sequences k=10, a 10-second average SAR is calculated as in (Expression 10).

$$10 \text{-} second average S A R ( W \text{/} kg ) = \frac{3 \times 10}{( 60 / 60 ) \times 10} = 3 ( W \text{/} kg ) \qquad ( 10 )$$

As described above, computation for predicting an average SAR based on a pulse sequence divided into N times is performed in step S362. In step S256, the CPU 71 determines whether or not a predicted value of the computed average SAR exceeds an SAR limit value. In a case where the predicted value of the average SAR exceeds the SAR limit value, the execution of the CPU 71 returns to step S252 in order to prompt an operator to change an imaging condition or the number of divisions N. On the other hand, in a case where the predicted value of the average SAR falls within and does not exceed the SAR limit value, the execution proceeds to step S260 of FIG. 2 in order to perform imaging.

### Example 2

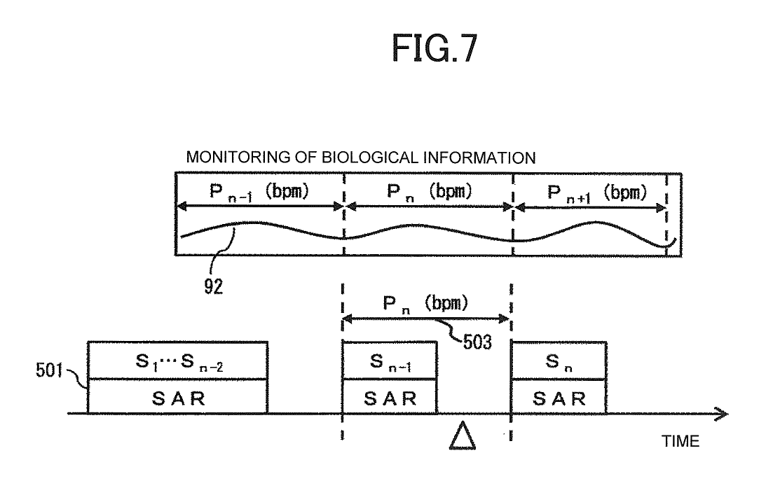

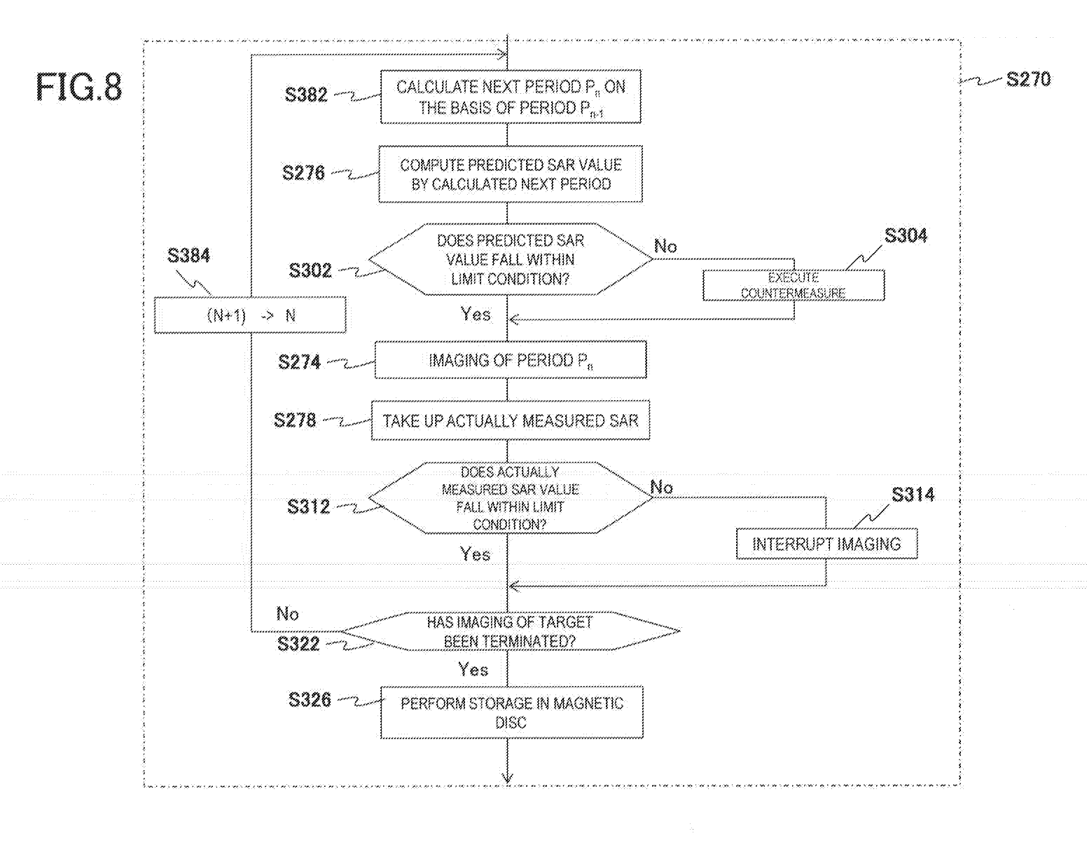

Example 2 of the invention includes contents related to SAR prediction during scanning. A description will be given using a table of FIG. 7 and a flow chart of FIG. 8. Meanwhile, the flow chart shown in FIG. 8 has processing contents that are substantially the same as those of the flow chart described in FIG. 4. Although essential processing contents of step S382 are the same as those of the corresponding step S272 of FIG. 4, the process of step S382 will be described again. Further, although step S384 of FIG. 8 basically includes the same procedure as that in FIG. 4, a description thereof is omitted in FIG. 4, and thus step S384 will also be described.

In the time table described in FIG. 7, an SAR is predicted on the basis of a change in the repetition of biological information 92. Next, imaging is performed in accordance with a pulse sequence, and an SAR is actually measured in the imaging. These operations are as shown in the flow chart of FIG. 8, and the specific operations are as described in FIG. 4.

Now, imaging and the measurement of biological information 92 in a period Pₙ₋₁ are completed in synchronization with an (n−1)-th period in a repetition period of the biological information 92, and a state is assumed in which an SAR of a pulse sequence for performing imaging in an n-th period which is the next period and the subsequent periods is predicted. Meanwhile, an SAR before the (n−1)-th period of the biological information 92 in the drawing is an actually measured SAR (501) which is measured by monitoring the SAR calculation unit 65. A period Pₙ of the biological information 92 which is an interval 503 between the (n−1)-th period and a Pₙ₊₁-th period of the biological information 92 has an undetermined value due to being measured.

In step S382 of FIG. 8, the period Pₙ of the biological information 92 is predicted using the value of the immediately previous period Pₙ₋₁ of the biological information 92. For example, the value of the period Pₙ₋₁ of the biological information 92 may be set to the period Pₙ. Next, as described in FIG. 4, in step S276, a 10-second average SAR and/or a 6-minute average SAR is calculated using the above-mentioned expression. The calculation is performed as follows on the basis of, for example, (Expression 11).

$$average S A R ( W \text{/} kg ) = \frac{{\sum }_{i = n}^{k} PowerSeq [ i ]}{{\sum }_{i = n}^{k} ( 60 / {P}_{n - 1} )} \qquad ( 11 )$$

For example, when an SAR of the divided pulse sequence is 2.4 (W/kg), a scanning time is 0.5 (sec), and a period Pₙ₋₁ is 80 (bpm), the number of pulse sequences k=13, and a 10-second average SAR is calculated as in (Expression 12). Meanwhile, there is also a method of obtaining a 10-second average SAR and a 6-minute average SAR that include an actually measured SAR in a monitor.

$$10 \text{-} second average S A R ( W \text{/} kg ) = \frac{2.4 \times 13}{( 60 / 80 ) \times 13} = 3.2 ( W \text{/} kg ) \qquad ( 12 )$$

As described above, predicted values of a 10-second average SAR and a 6-minute average SAR of biological information 92 in the next period are calculated. The next step S302 having been already described is performed, and imaging is performed in accordance with the operation of a pulse sequence in a period Pₙ of biological information 92 in step S274. Further, the execution proceeds to step S384 from step S322, and an order N allocated to a period is updated, thereby performing the same process on the next period of the biological information 92.

### Example 3

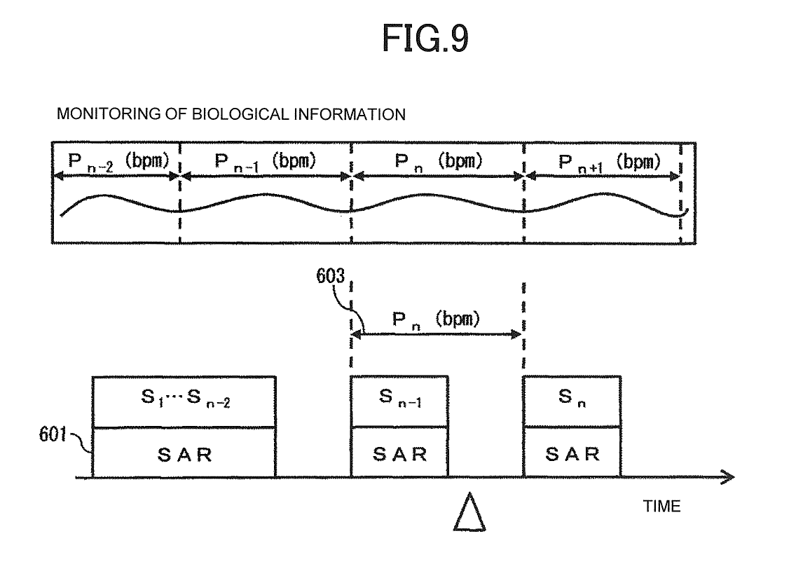

Example 3 of the invention includes contents related to SAR prediction during scanning. A description will be given using FIG. 9. FIG. 9 is a diagram showing the completion of synchronous measurement in an (n−1)-th period and the prediction of SARs of an n-th pulse sequence and the subsequent pulse sequences. An SAR before the (n−1)-th period is an actually measured SAR (601) in a monitor. A period Pₙ of biological information 92 which is an interval 603 between the (n−1)-th period and an (n+1)-th period has an undetermined value due to being measured. A period Pₙ is calculated using, for example, (Expression 13) from a value of the amount of variation (Pₙ₋₁-Pₙ₋₂) in the immediately previous period of the biological information, and an average SAR is calculated using (Expression 14). The amount of variation (Pₙ₋₁-Pₙ₋₂) of the period in (Expression 13) is as described above, and is a term for calculating variations in the previous period Pₙ₋₁ and the previous prior period Pₙ₋₂. That is, the previous period Pₙ₋₁ is corrected on the basis of the variations in the previous period Pₙ₋₁ and the previous prior period Pₙ₋₂. In this manner, it is possible to predict the next period in which imaging is to be performed from now with a high level of accuracy and to improve the prediction accuracy of a predicted SAR value.

Pₙ(bpm)=Pₙ₋₁+Pₙ₋₁−Pₙ₋₂ (13)

$$average S A R ( W \text{/} kg ) = \frac{{\sum }_{i = 1}^{k} PowerSeq [ i ]}{{\sum }_{i = 1}^{k} ( ScanTime [ i ] + 60 / {P}_{n} )} \qquad ( 14 )$$

For example, when an SAR of a pulse sequence divided is 2.1 (W/kg), a scanning time is 0.5 (sec), a previous period Pₙ₋₁ is 90 (bpm), and a previous prior period Pₙ₋₂ is 80 (bpm), Pₙ is set to 100 (bpm), the number of pulse sequences k=26, and a 10-second average SAR is calculated as in (Expression 15). Meanwhile, there is also a method of obtaining a 10-second average SAR and a 6-minute average SAR that include an SAR (601) which is actually measured in a monitor.

$$10 \text{-} second average S A R ( W \text{/} kg ) = \frac{2.1 \times 2.6}{( 60 / 100 ) \times 26} = 3.5 ( W \text{/} kg ) \qquad ( 15 )$$

Although a description of a flow chart related to this example is omitted, processing in this example can be performed by the processing method of the flow chart described in FIG. 4 or 8. For example, in step S272 of FIG. 4 or step S382 of FIG. 8, a tendency of a period of biological information 92, for example, the amount of variation between the previous period and the previous prior period is obtained from an actually measured value of the past period of the biological information 92 on the basis of the above-mentioned amount of variation (Pₙ₋₁-Pₙ₋₂) between periods, and a period Pₙ in which imaging is to be performed from now is calculated on the basis of the amount of variation. In FIG. 4 or 8, other steps can be referred as they are.

### Example 4

Example 4 of the invention includes contents related to SAR prediction during scanning. Similarly to Example 3, a description will be given using FIG. 9. In addition, a flow chart of processing to be performed is the flow chart shown in FIG. 4 which has been already described. In step S272 of the flowchart described in FIG. 4, a period Pₙ which is a period in which measurement is to be performed from now is calculated through the next process.

A process in step S272 is as follows. Regarding a period of biological information 92, a period Pₙ in which imaging is to be performed from now is calculated using (Expression 16) by providing a safety margin by the sum of an average value of a period P and a double of a standard deviation of P from statistical data.

Pₙ(bpm)=Average(P)+StdDeviation(P)×2 (16)

Further, an average SAR is calculated. For example, when an SAR of a pulse sequence divided is 2.4 (W/kg), a scanning time is 1 (sec), an average value of a period P is 90 (bpm), and a standard deviation of the period P is 2.5, a period Pₙ=95, the number of pulse sequences k=15, and a 10-second average SAR is calculated as in (Expression 17). Meanwhile, there is also a method of obtaining a 10-second average SAR and a 6-minute average SAR that include an actually measured SAR in a monitor.

$$10 \text{-} second average S A R ( W \text{/} kg ) = \frac{2.4 \times 15}{( 60 / 95 ) \times 15} = 3.8 ( W \text{/} kg ) \qquad ( 17 )$$

### Example 5

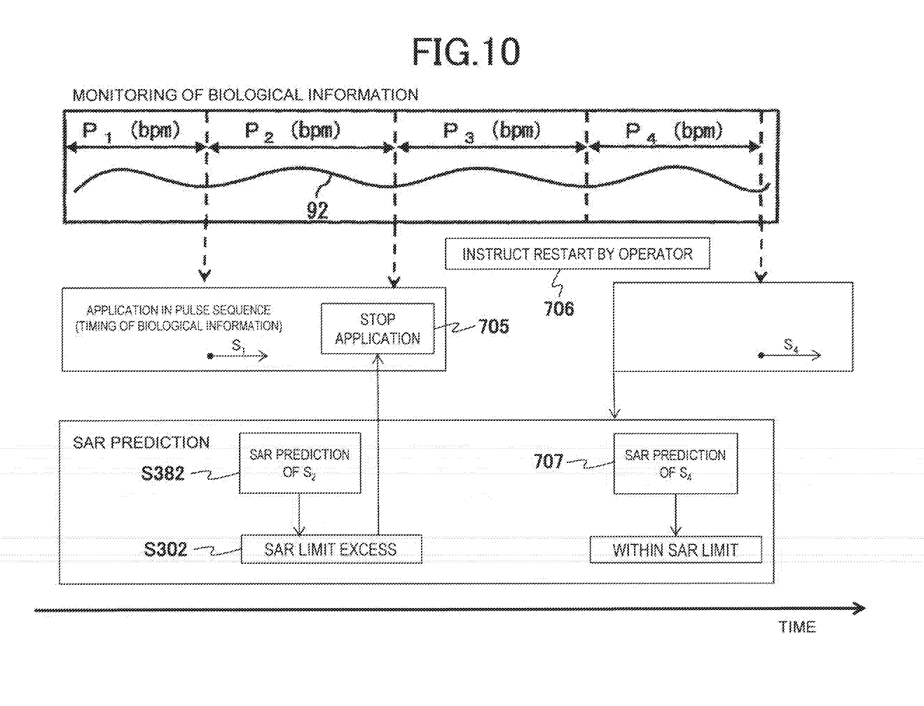

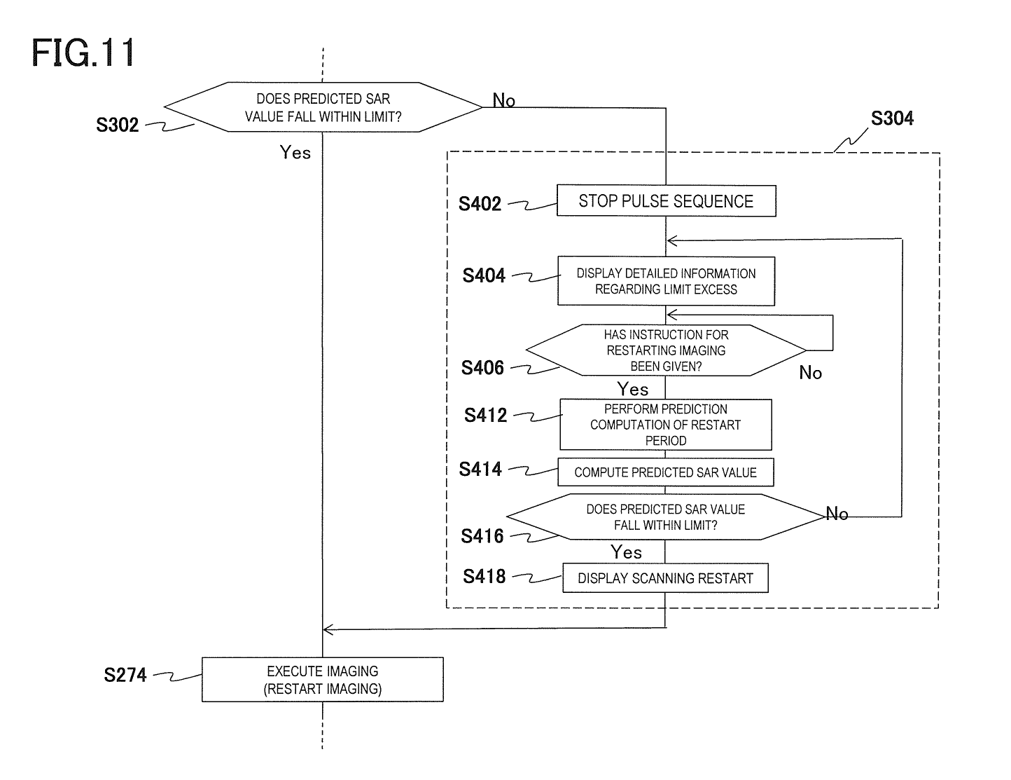

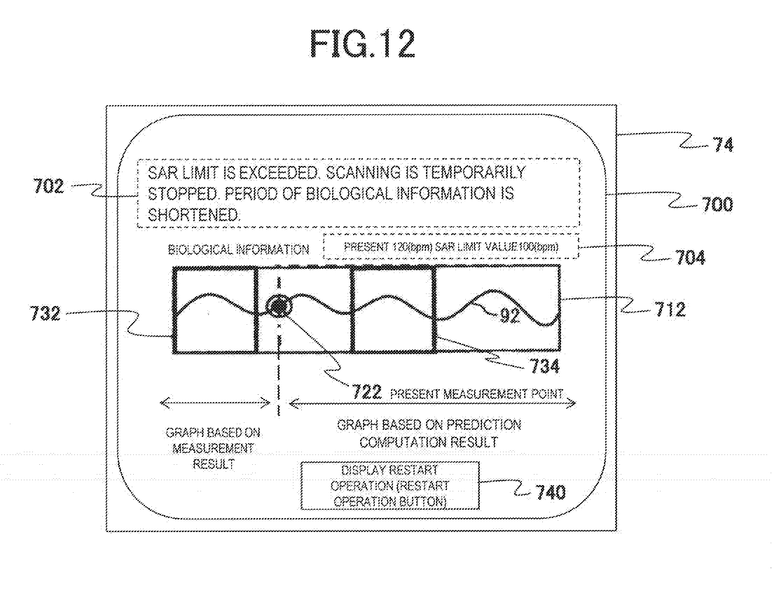

Example 5 of the invention will be described using a time table described in FIG. 10, a flow chart described in FIG. 11, and a display screen displayed on the display 74 described in FIG. 12. FIG. 10 is a time table shown an example in which an SAR is predicted using biological information 92 in the example described above using FIGS. 1 to 4 and Examples 1 to described above and a pulse sequence for imaging is temporarily stopped, that is, a scanning operation of the MRI apparatus 10 is temporarily stopped in a case where it is determined that the predicted SAR exceeds a limit.

Similarly, regarding any of the above-described example and Examples 1 to 4 described above, a process of stopping imaging or process of restarting imaging to be described next can be applied, but a description will be given in detail representatively using the examples described in FIGS. 7 and 8. An object 11 damages his or her health, and thus may have biological information 92 being in an extremely unstable state. For example, a cross-sectional image of the heart or a blood vessel image indicating the state of a blood vessel of the heart may be captured in synchronization with the movement of the heart because of a heart disease. An electrocardiogram is used as information indicting the movement of the heart, but the electrocardiogram may be disturbed. When the movement of the heart is suddenly quickened in a case where imaging is performed in synchronization with the electrocardiogram, an irradiation interval of an RF pulse emitted in synchronization with an electrocardiographic waveform suddenly becomes shorter, and thus a predicted SAR value may be suddenly increased. In this case, the predicted SAR value may exceed a limit value.

In step S382 of the flow chart described in FIG. 8, a period P₂ in which imaging is performed is predicted from a past period P₁ described in FIG. 10 or period information before the past period which is not shown in the drawing, and a computation process of predicting an SAR is performed in step S276 of FIG. 8 on the basis of the predicted period P₂. In step S302 described in FIG. 8, the CPU 71 determines whether or not the predicted SAR value exceeds a limit value. In a case where it is determined that the predicted SAR value exceeds the limit value, step S304 is performed. An example of specific processing contents of step S304 described in FIG. 8 is shown in FIG. 11.

In a case where it is determined that the predicted SAR value exceeds the limit value, the operation of a pulse sequence based on the operation of the sequencer 40 is stopped by the operation of the CPU 71 in order to stop irradiation with the RF pulse in step S402 constituting step S304 described in FIG. 11. In addition, in step S404, the reason for the operation of the pulse sequence being stopped, the predicted SAR value exceeding the limit value, and, for example, a change in a period reduction direction on which prediction computation is performed are displayed in a state display region 702 of the display 74.

An example of an operation image 700 displayed on the display 74 is described in FIG. 12. The operation image 700 may be displayed on the display 74 simultaneously with an MRI image being captured. A state display region 702 is provided in the operation image 700, and a scanning state such as a scanning stop state, the reason for stopping scanning, and the like are displayed in the state display region 702. Further, the display 74 is provided with a biological information display region 712, and thus a waveform of biological information 92 measured or a waveform based on the prediction of biological information 92 is displayed in the region.

As an example, the present point in time of the measurement of biological information 92 is displayed by a mark 722, and a graph prior to the mark 722 is displayed on the basis of a measurement result. Further, a graph on which prediction computation is performed from a measured value of the past biological information 92 is displayed in a direction later than the mark 722. A timing of scanning executed is displayed by a mark 732 in a graph of biological information 92 based on the past measurement result. Further, a timing of the next scanning in a case of the execution thereof is displayed by a mark 734 in a graph based on the prediction computation of biological information 92.

The mark 734 helps an operator to determine the restart of scanning.

In addition, a display 740 for performing an operation of restarting an imaging operation, for example, an operation button is displayed in the operation image 700, and it is possible to input an instruction for restarting the imaging operation to the MRI apparatus 10 by selecting the display 740. Further, an SAR display region 704 for displaying a predicted value of the present SAR value, an actually measured value of the past or present SAR value, or an SAR limit value is provided in the vicinity of the biological information display region 712 indicating the state of biological information 92.

An operator gives an instruction for restarting an imaging operation by selecting the display 740 with reference to information provided from the display 74, and the like. In step S406, the CPU 71 waits for the instruction for the restart which is given from the operator. When the instruction for the restart is given, the CPU 71 computes the length of a period (in this specification, the length of a period may be simply described as a period), which is indicated by the mark 734, for restarting imaging on the basis of an actually measured value of biological information 92 which periodically changes, in step S412. In step S414, the CPU 71 computes a predicted SAR value on the basis of the value of the computed period. It is determined whether or not the predicted SAR value satisfies a condition of being within a limit value by the execution of the CPU 71 in step S416. In a case where the value satisfies the condition of being within a limit value, a content indicating the restart of scanning for imaging is displayed in the operation image 700 of FIG. 12 in step S418. Further, after step S418 is performed, step S274 is performed, and imaging is restarted. Subsequently, step S278 described in FIG. 8 is performed, and the flow chart of FIG. 8 is performed below.

In a case where the predicted SAR value does not satisfy the condition of being within a limit value by the execution of step S416 described in FIG. 11, the execution of the CPU 71 proceeds to step S404 again from step S416, and the reason for the predicted SAR value not satisfying a condition of the restart of imaging is displayed in the state display region 702 of the operation image 700 displayed on the display 74.

In the operation image 700 described in FIG. 12, a graph based on actually measured data and a graph based on prediction computation may be displayed by different colors in the graph indicating biological information 92. In addition, in the graph of biological information 92, sections in which scanning for imaging is stopped may be displayed by different colors so as to perform highlighting indicating that scanning has not been performed. Further, highlighting such as the change of color of a section in which the computed predicted SAR value exceeds the limit value may be performed.

### Example 6

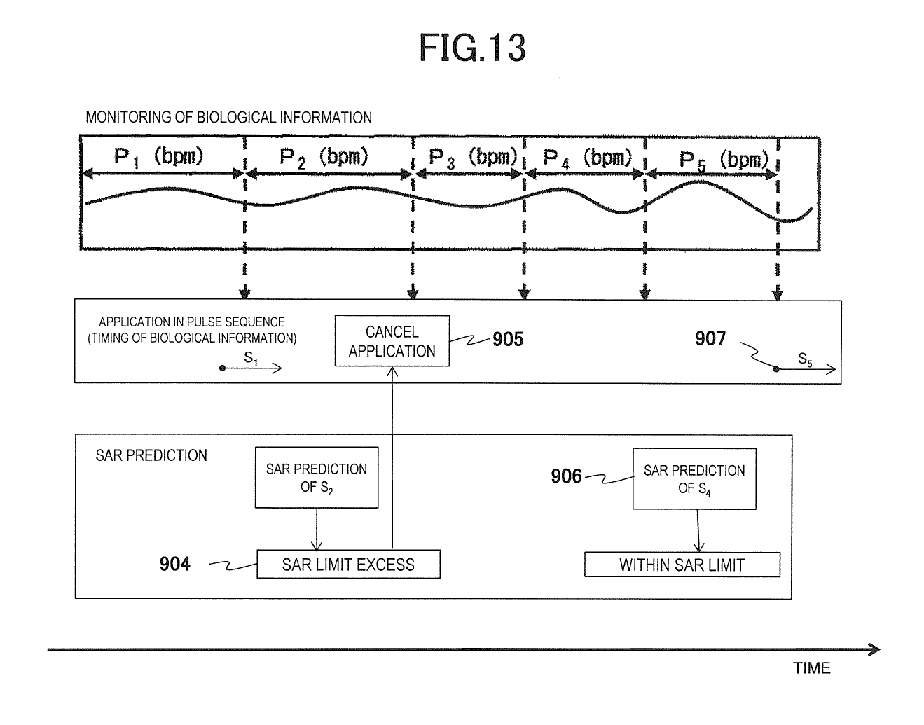

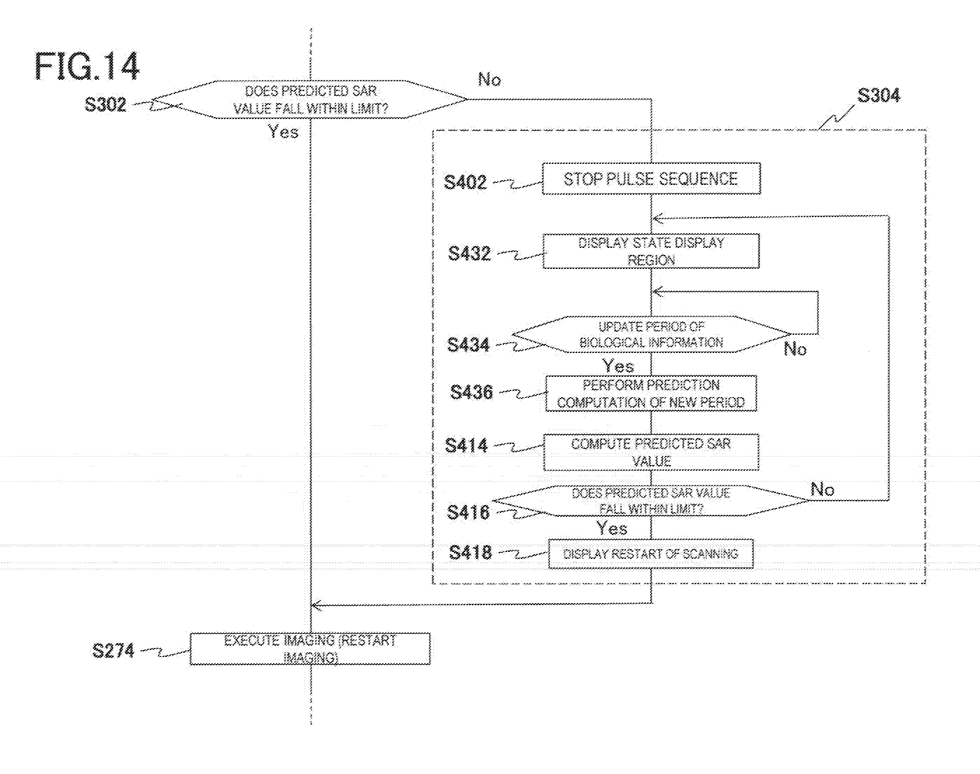

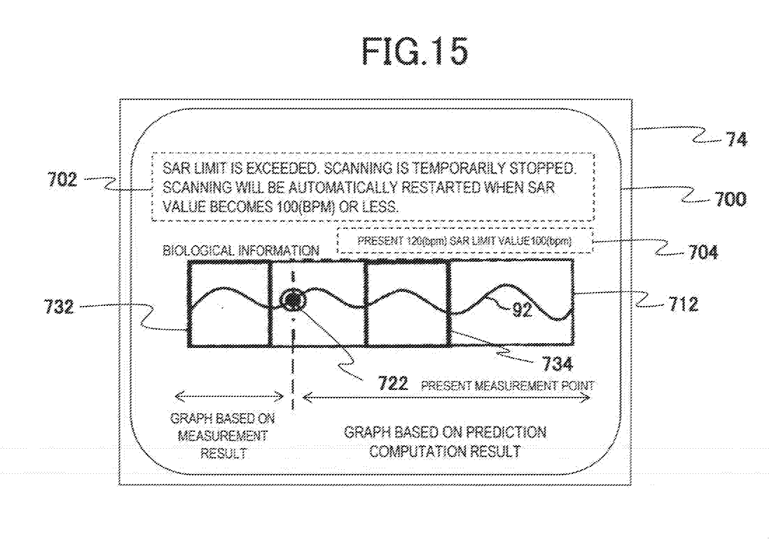

Example 6 of the invention will be described using FIG. 13 showing a time table, FIG. 14 showing a specific flow chart, and FIG. 15 showing an operation image 700 displayed on the display 74. This example is a diagram showing an example in which an SAR is predicted using biological information 92 in each of the above-described example and Examples 1 to 5 and application is canceled when the predicted SAR exceeds a limit. When SAR limit excess 904 is predicted due to a change in biological information, application cancellation 905 is performed.

The CPU 71 continuously performs SAR prediction 906 using biological information. When the CPU determines that a predicted SAR value falls within a limit, the CPU performs application restart 907 of the operation of a pulse sequence. When the above-mentioned temporarily stopping is performed, the contents thereof are displayed in a state display region 702 of the operation image 700 described in FIG. 15. A waveform of biological information 92 is displayed in a biological information display region 712 of the operation image 700, and highlighting such as the change of color of a section for which the processing unit 70 determines that a predicted SAR value exceeds a limit value is performed. This display also performs a function indicating that scanning has not been performed. In addition, a restart condition is also displayed in the state display region 702 of the operation image 700. An operator of the MRI apparatus 10 can accurately ascertain an execution state of imaging, for example, a scanning state by performing the display.

A flow chart of the operation to be performed by the CPU 71 is described in FIG. 14. Meanwhile, procedures denoted by the same reference numeral as those of other drawings include substantially the same process and exhibit substantially the same effect. In step S382 described in FIG. 8, prediction computation of the length of a period of biological information 92 on which a process based on a pulse sequence is to be performed from now is performed. Subsequently, an SAR is predicted and computed in step S276 on the basis of the period on which the prediction computation is performed. In step S302, the CPU 71 determines whether or not the value of the SAR having been subjected to the prediction computation exceeds a limit value in step S276. In a case where it is determined that the value of the SAR having been subjected to the prediction computation exceeds the limit value, step S402 described in FIG. 14 is performed, and the operation of a pulse sequence is stopped. In this manner, irradiation with an RF pulse with respect to an object 11 is stopped.

In step S432, the temporarily stopping of a scanning operation and an automatic restart condition are displayed in the state display region 702 of the operation image 700 which is described in FIG. 15 as described above. In this example, the restart of a scanning operation which is an imaging operation by a predicted SAR value satisfying the limit condition as the automatic restart condition is displayed. Further, 120 (bpm) which is the present SAR prediction computation value is displayed in contrast with a limit value of 100 (bpm) in an SAR display region 704.

In step S434, it is determined whether or not an SAR prediction computation timing with respect to the next period is reached. Since a scanning operation based on the operation of a pulse sequence which is an imaging operation is performed in synchronization with a change in biological information 92, the SAR prediction computation is performed so as to be substantially synchronized with the change in the biological information 92. For this reason, it is determined in step S434 whether the SAR prediction computation timing for the next period has been reached.

The prediction computation of the length of the next period is performed in step S436 in a state where the SAR prediction computation timing for the next period is reached. This computation method may be performed on the basis of (Expression 13) mentioned above, or any of the above-mentioned other methods may be performed. Next, a predicted SAR value is computed in step S414 on the basis of a predicted value of the computed length of the period. In step S416, the CPU 71 determines whether or not the predicted SAR value falls within a limit value range. In a case where the predicted SAR value falls within the limit value range, the restart of imaging, that is, the restart of scanning is displayed in the state display region 702 of the operation image 700 of FIG. 15 in step S418, and step S274 is performed. The subsequent processing is as described in FIG. 8 and the like.

In a case where it is determined in step S416 that the predicted SAR value exceeds the limit value, the execution of the CPU 71 proceeds to step S432 from step S416, and a content indicating that the predicted SAR value exceeds the limit value even in the next period is displayed in the state display region 702 of the operation image 700. In step S434, a change in biological information 92, and the measurement of biological information 92 and the adjustment of a computation timing of the predicted SAR value that are respectively performed in step S436 and step S414 are performed, and a processing with respect to the next period is repeatedly performed.

In a case where a period of the change in biological information 92 variously changes due to a disease of an object 11, it is automatically determined whether or not a predicted SAR value falls within a limit value range in this example, and the temporary stopping of imaging and the restart of imaging are performed by the CPU 71 on the basis of a result of the determination, thereby allowing the operability of the MRI apparatus 10 to be improved. In addition, a highly reliable imaging operation can be performed. However, in addition to performing a method which is completely automatically performed by the CPU 71, a restart process may be performed by instructing the CPU 71 to perform confirmation. The CPU 71 performs many functions, and thus an operator's burden is drastically reduced.

### Example 7

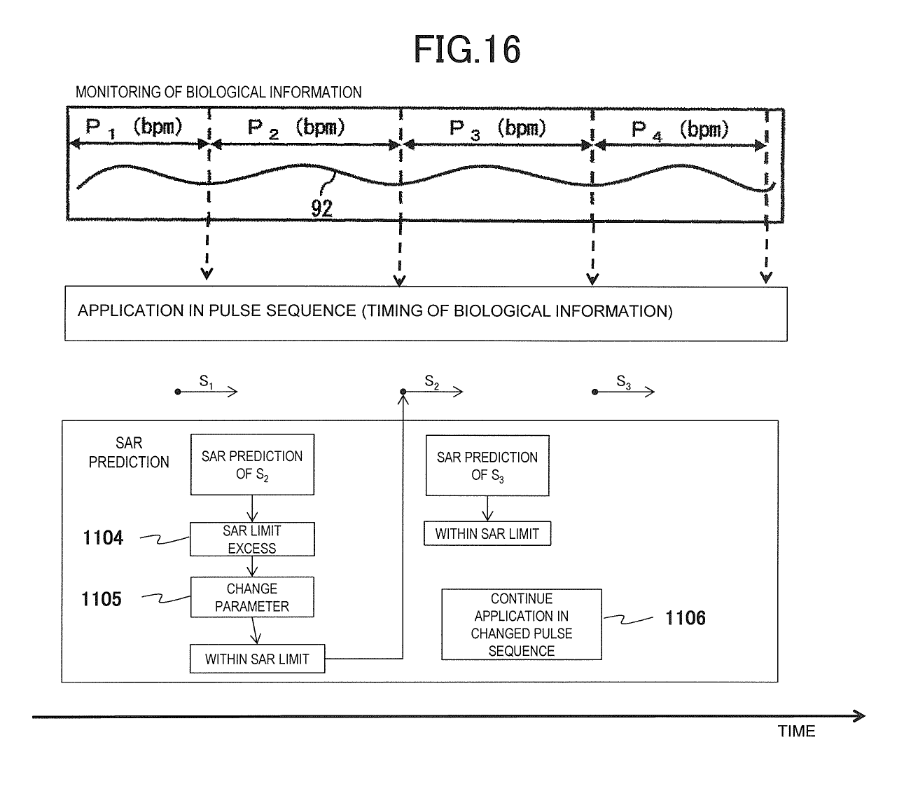

Example 7 of the invention will be described using FIGS. 16 to 18. FIG. 16 is a diagram showing an example in which an SAR is predicted using biological information in the above-described example and the other 1 to 4, a change to an imaging parameter, that is, an imaging condition in which a limit of the SAR is not exceeded is performed when the predicted SAR exceeds the limit, and scanning is continuously performed. Meanwhile, in this example, an operator may perform a confirmation operation on a changing plan of the CPU 71, instead of being limited to an example in which an imaging condition is automatically changed. In addition, the CPU 71 may propose a plurality of changing plans, and an operator may select the changing plan to determine a new imaging condition.

A predicted SAR value is set to SAR limit excess 1104 due to a change in biological information. When the CPU 71 computes the predicted SAR value and predicts that the computed predicted SAR value exceeds an SAR limit value, the CPU 71 computes a sequence parameter, that is, an imaging condition in which the predicted SAR value falls within an SAR limit, and parameter change 1105 which is an imaging condition is performed. Here, the change of the sequence parameter which is an imaging condition may be automatically performed by the CPU 71, or a change content of the CPU 71 may be displayed in an operation image 700 of the display 74 and may be confirmed by an operator to be changed. Further, the change may be performed using a method of allowing the CPU 71 to propose a changing plan and allowing an operator to select the changing plan to determine a sequence parameter which is a new imaging condition.

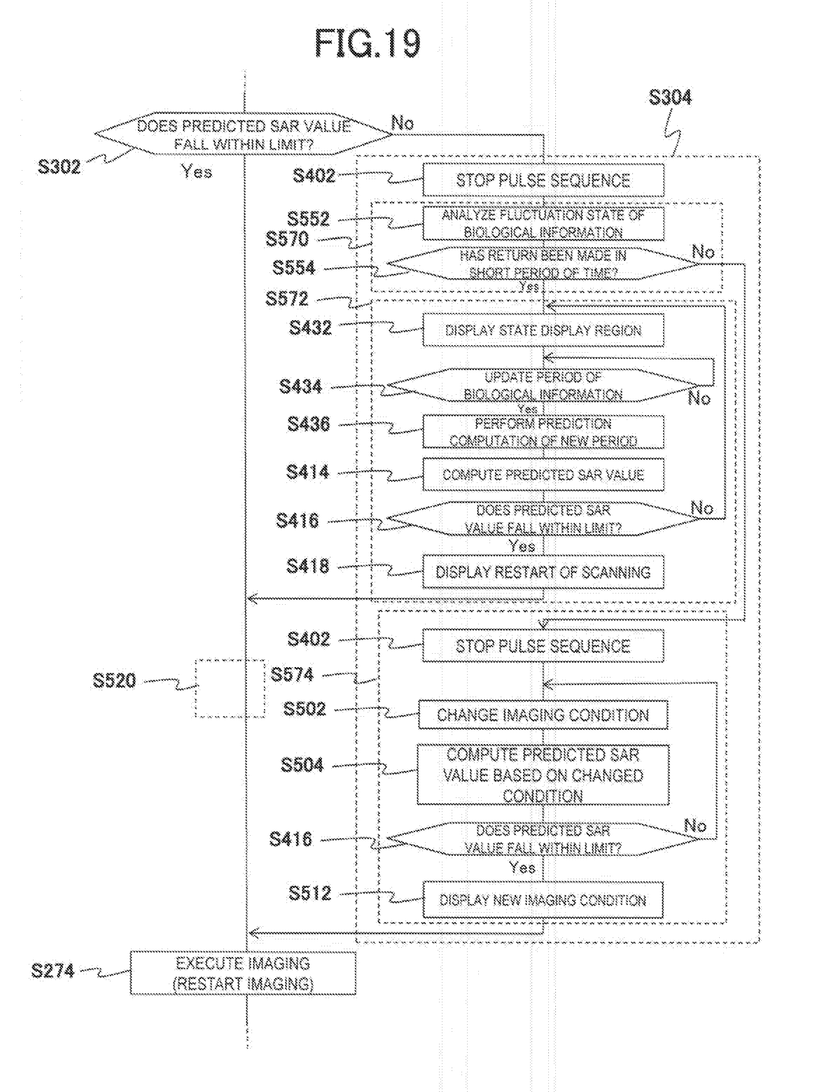

Application continuation 1106 in a pulse sequence which is continuation of the operation of a pulse sequence is performed in accordance with a sequence parameter which is a new changed imaging condition. The changed sequence parameter is displayed in, for example, an area 706 of an operation image 700 shown in FIG. 19 as an information dialogue window so as to be easily understood by an operator. As an example, the changed sequence parameter and a ratio of SAR relaxation are displayed in the area 706. Further, similarly to the above-mentioned example, a waveform of biological information 92 is displayed in a biological information display region 712 of the operation image 700, and highlighting such as a change of color is performed on a section in which the sequence parameter is changed, for example, a section indicated by a mark 734, which indicates the relaxation of an SAR and the execution of scanning.

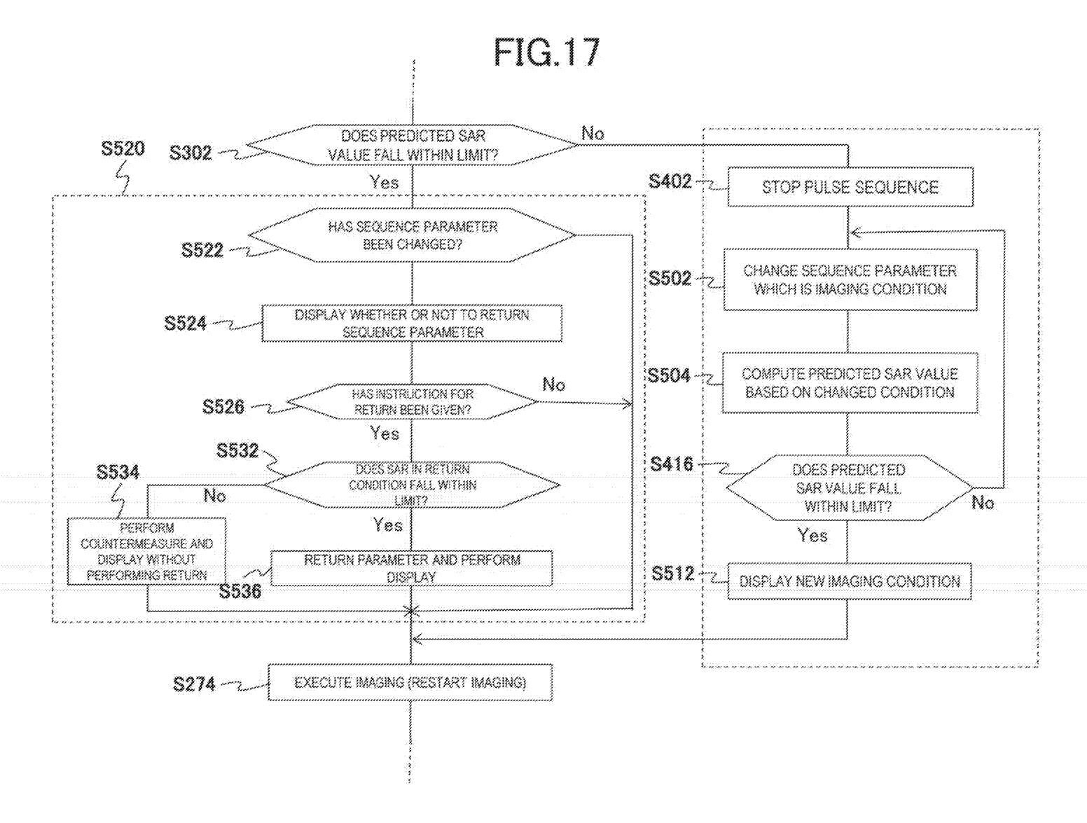

An operation procedure of the CPU 71 for performing an operation of a time table described in FIG. 16 is shown in FIG. 17. In step S302 described in FIG. 4 or 8, in a case where the predicted SAR value exceeds the limit, the execution of the CPU 71 proceeds to step S304 from step S302. In step S402 constituting step S302, the operation of a pulse sequence is stopped, and a parameter of the pulse sequence which is an imaging condition is changed in step S502. In step S502, as described in the parameter change 1105 of FIG. 17, a sequence parameter may be automatically changed by the CPU 71, or a change based on an operator's instruction may be performed by allowing the CPU 71 to propose a changing plan and allowing the operator to select the plan. Meanwhile, in a case where the CPU 71 completely automatically changes a sequence parameter, step S504 or step S416 may not be present. However, even when the sequence parameter is completely automatically changed, reliability is improved by performing step S504 or step S416. In addition, in a case where an operator's instruction is added, reliability is further improved by performing step S504 or step S416.

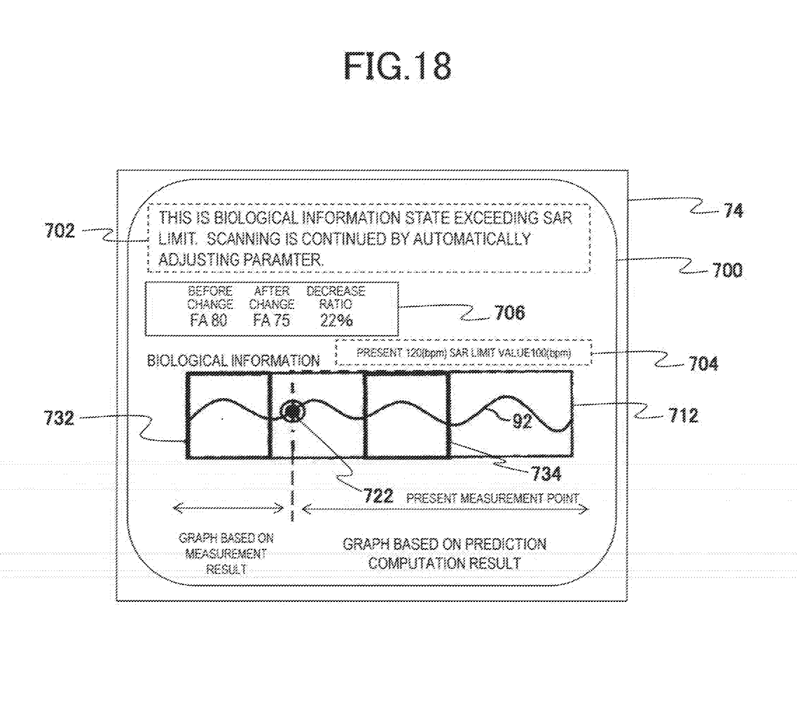

In step S504, a predicted SAR value is computed on the basis of the changed sequence parameter which is an imaging condition. It is determined in step S416 whether or not the computed predicted SAR value exceeds a limit value. In a case where, the computed predicted SAR value does not exceed the limit value, the execution of the CPU 71 proceeds to step S512 from step S416. In step S512, a new sequence parameter is displayed in the area 706 of FIG. 18 as described above, and the execution proceeds to step S274, thereby restarting an imaging operation in accordance with the new sequence parameter. Hereinafter, the imaging operation is promoted under the control of the CPU 71 in accordance with the above-described procedure.

The subsequent imaging operation may be continued in accordance with the sequence parameter changed in step S502, but the changed sequence parameter may be returned to its original state. A process of returning the changed sequence parameter to its original state is performed according to a procedure indicated by step S520. In a case where the predicted SAR value falls within the limit range in step S302, step S520 is performed by the CPU 71, and it is determined in step S522 whether or not the sequence parameter has been changed. When the sequence parameter has not been changed, the process of returning the sequence parameter to its original state may not be performed in 520, and thus the execution of the CPU 71 proceeds to step S274 from step S522, and an imaging operation is promoted.

On the other hand, in a case where the sequence parameter has been changed, a request for an instruction of whether or not to return the sequence parameter to its original state is displayed in the operation image 700 in step S524, and an operator's instruction is determined in step S526. When the operator's instruction is an instruction for continuously performing imaging using the changed sequence parameter without returning the changed sequence parameter to its original state, the execution of the CPU 71 proceeds to step S274 from step S526 to continuously perform the imaging operation in accordance with the changed sequence parameter.

When the operator's instruction is an instruction for returning the changed sequence parameter to its original state, a predicted SAR value is computed in accordance with an imaging condition for returning the sequence parameter to its original state in step S532, and it is determined whether or not the predicted SAR value which is a computation result exceeds a limit value. In a case where the predicted SAR value according to the imaging condition for returning the sequence parameter to its original state falls within a limit according to the determination in step S532, the sequence parameter is returned to its original value in step S536. In addition, the return to the original state is displayed in the operation image 700 in step S536. On the other hand, in a case where the predicted SAR value according to the imaging condition for returning the sequence parameter to its original state exceeds the limit, a process of not returning the sequence parameter to its original state is performed in step S534, and no return of the sequence parameter is displayed in the operation image 700. In this case, step S520 is performed again in a process synchronized with the next period, and a process of whether or not to return the sequence parameter to its original state is performed.

### Example 8

FIG. 19 shows still another example. A countermeasure in a case where a predicted SAR value exceeds a limit value has been already described in step S572 (see FIG. 19) which is a method described in FIG. 14 and step S574 (see FIG. 19) which is a method described in FIG. 18. Each of the processes of step S572 and step S574 has a peculiar advantage, and thus it is possible to exhibit a greater effect by properly using the methods. An example of determination of the properly using of the methods is shown in step S570 of FIG. 19.

It is determined which of step S572 and step S574 is to be performed by stopping the operation of a pulse sequence in step S402 and performing step S570. The state of biological information 92 is analyzed in step S552 of step S570. For example, the CPU 71 determines whether the length of a period of biological information 92 is fluctuating or is stabilized, whether a period of biological information 92 is repeated in a state where a predicted SAR value is almost an SAR limit value, and whether a period of biological information 92 is repeated in a state where a predicted SAR value greatly exceeds an SAR limit value.

In a case where the CPU 71 determines that a change in a period of biological information 92 returns to its original state in a short period of time according to such an analysis result of the CPU 71 in step S552, step S572 described in FIG. 14 is selected. A case where step S572 is selected includes a case where a period of an electrocardiographic waveform is temporarily disturbed due to, for example, an irregular pulse.

In a case where the CPU 71 determines that a period of biological information 92 does not return to its original state in a short period of time according to the above-mentioned analysis result of the CPU 71 in step S552, step S574 described in FIG. 18 is selected, and thus a method of changing a sequence parameter is performed. An example of this state includes a case where the pulse of a heart gradually increases, which results in a state where a predicted SAR value exceeds a limit value. In this case, it is determined that the increased pulse of the heart is not simply reduced, and thus a sequence parameter is changed by step S574 and imaging is performed. In this case, the process of step S520 may be performed or may not be performed.

Details of step S572 and step S574 have been already described, and thus a description thereof will be omitted.

Meanwhile, the state of selection of step S572 or step S574 is displayed, for example, in a state display region 702 of an operation image 700 in step S432 or step S502 during the execution of step S572 or step S574. Thereby, an operator can exactly and accurately ascertain a situation, and a highly reliable operation is performed.

As described above, the examples of the invention have been described, but the invention is not limited thereto.

### REFERENCE SIGNS LIST

10: MRI APPARATUS
11: OBJECT
20: STATIC MAGNETIC FIELD SPACE
30: GRADIENT MAGNETIC FIELD GENERATION UNIT
31: GRADIENT MAGNETIC FIELD COIL
32: GRADIENT MAGNETIC FIELD POWER SUPPLY
40: SEQUENCER
50: HIGH FREQUENCY MAGNETIC FIELD GENERATION UNIT
51: HIGH FREQUENCY OSCILLATOR
52: MODULATOR
53: HIGH FREQUENCY AMPLIFIER
54: TRANSMISSION COIL
60: SIGNAL DETECTION UNIT
61: A/D CONVERTER
62: QUADRATURE PHASE DETECTOR
63: SIGNAL AMPLIFIER
64: RECEPTION COIL
65: SAR CALCULATION UNIT
70: PROCESSING UNIT
71: CPU
72: MEMORY
73: MAGNETIC DISC
74: DISPLAY
80: OPERATION UNIT
81: TRACKBALL, MOUSE, OR PAD
82: KEYBOARD
90: BIOLOGICAL INFORMATION RECEPTION UNIT

1. A magnetic resonance imaging apparatus comprising:
a static magnetic field generation unit that generates a static magnetic field in a space in winch an object is accommodated;
a gradient magnetic field generation unit that generates a gradient magnetic field so as to be superimposed on the static magnetic field;
a high frequency magnetic field generation unit that generates a high frequency magnetic field to be emitted to the Object;
a sequencer that controls the generation of the gradient magnetic field and the generation of the high frequency magnetic field in accordance with a pulse sequence;
a signal detection unit that detects a nuclear magnetic resonance signal;
control unit that computes a predicted SAR value; and
a biological information reception unit that receives biological information of the object,
wherein the sequencer controls the generation of the gradient magnetic field and the generation of the high frequency magnetic field in synchronization with the biological information,
wherein the control unit computes a predicted SAR value to determine whether or not the predicted SAR value exceeds a limit value, on the basis of a length of a period of the biological information, and
wherein the generation of the gradient magnetic field and the generation of the high frequency magnetic field are controlled to perform an imaging operation on the basis of the control unit determining that the predicted SAR value does not exceed the limit value, and an MRI image is generated on the basis of the nuclear magnetic resonance signal detected by the signal detection unit.

2. The magnetic resonance imaging apparatus according to claim 1,
wherein the control unit obtains a length of a period in which an imaging operation is to be subsequently performed, by computation,
wherein the control unit further computes a predicted SAR value in the period in which an imaging operation is to be subsequently performed, on the basis of the obtained length of the period, and
wherein it is determined whether or not the predicted SAR value exceeds the limit value, on the basis of the computed predicted SAR value.

3. The magnetic resonance imaging apparatus according to claim 2,
wherein the control unit obtains a change related to a period of biological information by computation on the basis of the received biological information, and computes a length of a period in which an imaging operation is to be subsequently performed, on the basis of the received biological information and the computed change in the computed period.

4. The magnetic resonance imaging apparatus according to claim 2,
wherein the control unit computes a length of a period in which an imaging operation is to be subsequently performed, by a statistical process of the biological information received, and obtains the predicted SAR value by computation in accordance with the computed length of the period.

5. The magnetic resonance imaging apparatus according to claim 1,
wherein the number of times N for dividing the imaging operation according to the period of the biological information is set, and the control unit computes an irradiation power of the high frequency magnetic field generation unit in each period of the imaging operation divided into N times, and
wherein the control unit computes the predicted SAR value in each of the periods obtained by the division performed on the basis of the computed irradiation power, and performs the imaging operation in accordance with the computed predicted SAR value.

6. The magnetic resonance imaging apparatus according to claim 2,
wherein the control unit determines whether or not the predicted SAR value exceeds the limit value, and the imaging operation is stopped in a case where the predicted SAR value exceeds the limit value, and
wherein the control unit restarts the imaging operation in accordance with an instruction for restarting the imaging operation.

7. The magnetic resonance imaging apparatus according to claim 6,
wherein the control unit performs prediction computation of the length of the period in which the imaging operation is expected to be restarted, computes a predicted SAR value related to the period in which the imaging operation is expected to be restarted, on the basis of a prediction computation value of the obtained length of the period, and restarts the imaging operation in a case where the computed predicted SAR value does not exceed the limit value.

8. The magnetic resonance imaging apparatus according to claim 6,
wherein a display is further provided, a biological information display region is provided in the display, and a waveform of biological information is displayed in the biological information display region, and
wherein an operation display for instructing the restart is displayed on the display, and an instruction for restarting the imaging operation is input by the operation display being operated.

9. The magnetic resonance imaging apparatus according to claim 2,
wherein a length of a period in which an imaging operation is to be subsequently performed is computed on the basis of a change in the computed period,
wherein the predicted SAR value related to a period in which an imaging operation is to be subsequently performed is computed in accordance with the computed length of the period in which an imaging operation is to be subsequently performed,
wherein it is determined whether or not the computed predicted SAR value exceeds the limit value,
wherein in a case where the predicted SAR value does not exceed the limit value, an imaging operation is performed on the period in which an imaging operation is to be subsequently performed,
wherein in a case where the computed predicted SAR value exceeds the limit value, the imaging operation is interrupted,
wherein a length of the next period is further computed, a predicted SAR value of the next period is computed on the basis of the computed length of the next period, and it is determined whether or not the computed predicted SAR value of the next period exceeds the limit value, and
wherein, in this manner, it is determined whether or not the predicted SAR values exceed the limit value in order in response to the period of the biological information, and an imaging operation is restarted in a period in which the predicted SAR value does not exceed the limit value.

10. The magnetic resonance imaging apparatus according to claim 9,
wherein a display is further provided, a biological information display region and a SAR display region are provided in the display, biological information is displayed in the biological information display region, and the computed predicted SAR value is displayed in the SAR display region.

11. The magnetic resonance imaging apparatus according to claim 2,
wherein the control unit determines whether or not the predicted SAR value exceeds the limit value, and the imaging operation is stopped in a case where the predicted SAR value exceeds the limit value, and
wherein the control unit changes a sequence parameter for imaging, and an imaging operation is restarted on the basis of the changed sequence parameter.

12. The magnetic resonance imaging apparatus according to claim 11,
wherein a display is further provided, and the sequence parameter before the change and the sequence parameter after the change are displayed on the display.

13. The magnetic resonance imaging apparatus according to claim 11,
wherein in an imaging operation based on the changed sequence parameter, it is determined whether or not a predicted SAR value based on the sequence parameter before the change exceeds the limit value, and the sequence parameter is returned to the sequence parameter before the change in a case where the predicted SAR value based on the sequence parameter before the change does not exceed the limit value.

14. The magnetic resonance imaging apparatus according to claim 2,
wherein the control unit determines whether or not the predicted SAR value exceeds the limit value, and the imaging operation is stopped in a case where the predicted SAR value exceeds the limit value,
wherein the control unit determines whether to perform first countermeasure processing for changing a sequence parameter for imaging in order to make the predicted SAR value not exceed the limit value or whether to perform second countermeasure processing for waiting for setting of a state where the predicted SAR value does not exceed the limit value by a change in the length of the period of the biological information, on the basis of a state of the biological information,
wherein in a case where the control unit selects the first countermeasure processing, the control unit changes the sequence parameter for imaging to restart an imaging operation, and
wherein in a case where the control unit selects the second countermeasure processing, the control unit predicts the length of the period of the biological information to compute the predicted SAR value, repeats a determination process of whether or not the computed predicted SAR value exceeds the limit value, and restarts an imaging operation on the basis of a determination result indicating that the predicted SAR value does not exceed the limit value.

15. A method of controlling a magnetic resonance imaging apparatus, the method comprising:
generating a static magnetic field in a space in which an object is accommodated;
generating a gradient magnetic field so as to be superimposed on the static magnetic field;
generating a high frequency magnetic field to be emitted to the object;
detecting a nuclear magnetic resonance signal generated by the object;
receiving biological information of the object;
controlling the generation of the gradient magnetic field and the generation of the high frequency magnetic field in synchronization with the received biological information; and
predicting a length of a period of the biological information, computing a predicted SAR value on the basis of the predicted length of the period of the biological information, and determining that the computed predicted SAR value does not exceed a limit value, to thereby perform an imaging operation in synchronization with the biological information.
